(19) United States
(12) Patent Application Publication
(10) Pub. No.: US 2026/0107511 A1
(43) Pub. Date: Apr. 16, 2026

(54) SEMICONDUCTOR STRUCTURE AND METHOD FOR FORMING THE SAME

(71) Applicant: TAIWAN SEMICONDUCTOR MANUFACTURING COMPANY, LTD., Hsinchu (TW)

(72) Inventors: Ming-Heng TSAI, Taipei City (TW); Ta-Chun LIN, Hsinchu (TW); Hong-Chih CHEN, Changhua County (TW); Jhon Jhy LIAW, Hsinchu County (TW)

(73) Assignee: TAIWAN SEMICONDUCTOR MANUFACTURING COMPANY, LTD., Hsinchu (TW)

(21) Appl. No.: 18/912,903

(22) Filed: Oct. 11, 2024

(51) Int. Cl. H01L 29/423; H01L 21/8234; H01L 27/088; H01L 29/06; H01L 29/66; H01L 29/775; H01L 29/786

(52) U.S. Cl. CPC H10D 30/6735; H10D 30/014; H10D 30/43; H10D 30/6757; H10D 62/121; H10D 64/017; H10D 64/519; H10D 84/0128; H10D 84/013; H10D 84/038; H10D 84/83

(57) ABSTRACT

A semiconductor structure includes a first group of a first transistor and a second transistor, the first and second transistors being arranged along a first direction, wherein the first and second transistors includes channel regions having a width W1 along the first direction, and the first and second transistors include a distance S1 therebetween. The semiconductor structure includes a second group of third transistor and a fourth transistor, the third and fourth transistors being arranged along the first direction, wherein the third and fourth transistors includes channel regions having a width W2 along the first direction, and the third and fourth transistors include a distance S2 therebetween, and wherein W2+S2 is greater than W1+S1.

### BACKGROUND

The semiconductor integrated circuit (IC) industry has experienced rapid growth. Technological advances in IC materials and design have produced generations of ICs. Each generation has smaller and more complex circuits than the previous generation. However, these advances have increased the complexity of processing and manufacturing ICs. In the course of IC evolution, functional density (i.e., the number of interconnected devices per chip area) has generally increased while geometric size (i.e., the smallest component (or line) that can be created using a fabrication process) has decreased. This scaling-down process generally provides benefits by increasing production efficiency and lowering associated costs. However, since feature sizes continue to decrease, fabrication processes continue to become more difficult to perform. Therefore, it is a challenge to form reliable semiconductor devices at smaller and smaller sizes.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1A illustrates a top view of an integrated circuit in accordance with some embodiments of the present disclosure.

FIGS. 1B to 1G illustrate cross-sectional views of an integrated circuit in accordance with some embodiments of the present disclosure.

FIGS. 2A to 15D illustrate a method in various stages of forming a semiconductor device in accordance with some embodiments of the present disclosure.

FIG. 16 illustrates a top view of an integrated circuit in accordance with some embodiments of the present disclosure.

FIG. 17 illustrates a top view of an integrated circuit in accordance with some embodiments of the present disclosure.

FIG. 18 illustrates a top view of an integrated circuit in accordance with some embodiments of the present disclosure.

FIG. 19 illustrates a top view of an integrated circuit in accordance with some embodiments of the present disclosure.

FIG. 20 illustrates a top view of an integrated circuit in accordance with some embodiments of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly. As used herein, “around,” “about,” “approximately,” or “substantially” may generally mean within 20 percent, or within 10 percent, or within 5 percent of a given value or range. Numerical quantities given herein are approximate, meaning that the term “around,” “about,” “approximately,” or “substantially” can be inferred if not expressly stated. One skilled in the art will realize, however, that the values or ranges recited throughout the description are merely examples, and may be reduced or varied with the down-scaling of the integrated circuits.

The gate all around (GAA) transistor structures may be patterned by any suitable method. For example, the structures may be patterned using one or more photolithography processes, including double-patterning or multi-patterning processes. Generally, double-patterning or multi-patterning processes combine photolithography and self-aligned processes, allowing patterns to be created that have, for example, pitches smaller than what is otherwise obtainable using a single, direct photolithography process. For example, in one embodiment, a sacrificial layer is formed over a substrate and patterned using a photolithography process. Spacers are formed alongside the patterned sacrificial layer using a self-aligned process. The sacrificial layer is then removed, and the remaining spacers may then be used to pattern the GAA structure.

In the present disclosure, at least one complementary FET (CFET) is provided, and its manufacturing method will be disclosed in the following discussion. In a CFET, a first transistor is disposed over a substrate (not shown), and a second transistor is disposed vertically above the first transistor. In some embodiments, the first transistor and the second transistor may be field effect transistor (FET) and may both include gate-all-around (GAA) configuration, and thus the first transistor and the second transistor can also be referred to as GAA FETs. The first transistor includes first semiconductor channel layers vertically stacked one above another, a first metal gate structure wrapping around each of the first semiconductor channel layers, and first source/drain epitaxy structures on opposite ends of each of the first semiconductor channel layers. Similarly, the second transistor includes second semiconductor channel layers vertically stacked one above another, a second metal gate structure wrapping around each of the second semiconductor channel layers, and second source/drain epitaxy structures on opposite ends of each of the second semiconductor channel layers.

In some embodiments, the first transistor has a first conductivity type and the second transistor has a second conductivity type different from the first conductivity type. For example, the first transistor may be an n-type transistor (e.g., N-FET), and the second transistor may be a p-type transistor (e.g., P-FET). However, in other embodiments, the first transistor may be a p-type transistor (e.g., P-FET), and the second transistor may be an n-type transistor (e.g., N-FET). For an n-type transistor, the source/drain epitaxy structures may include n-type dopants, such as phosphorus (P), arsenic (As), or antimony (Sb), or the like. For a p-type transistor, the source/drain epitaxy structures may include p-type dopants, such as boron (B), gallium (Ga), indium (In), aluminium (Al), or the like.

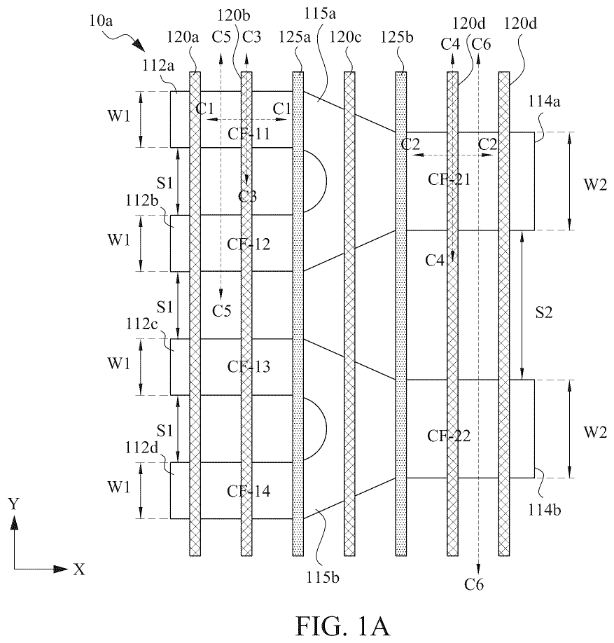

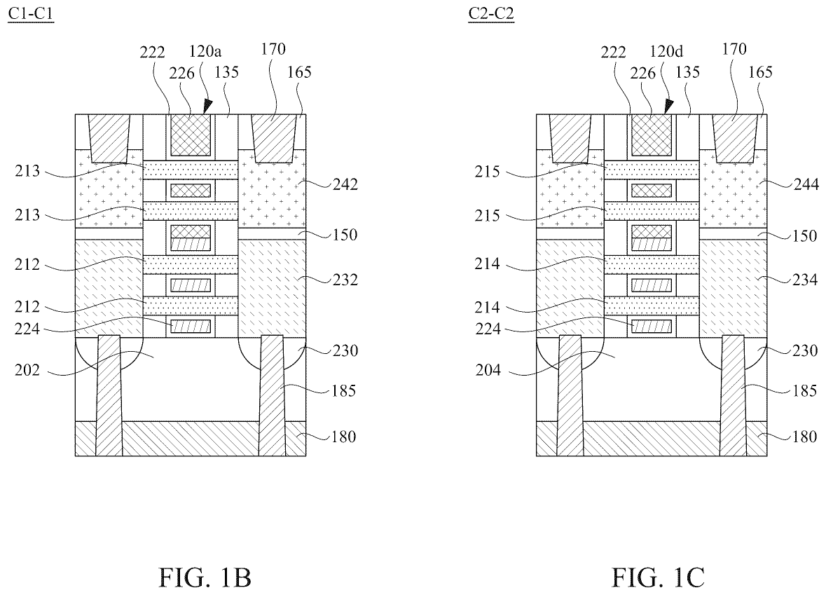

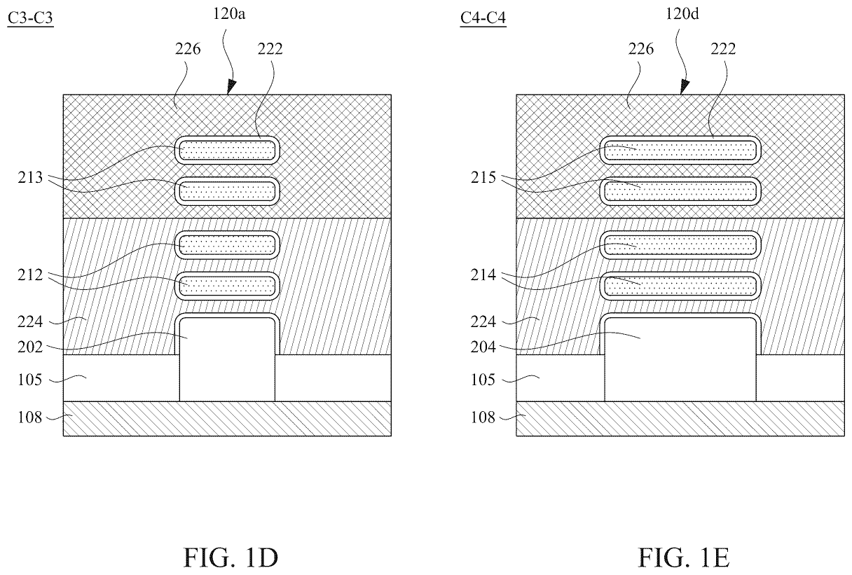

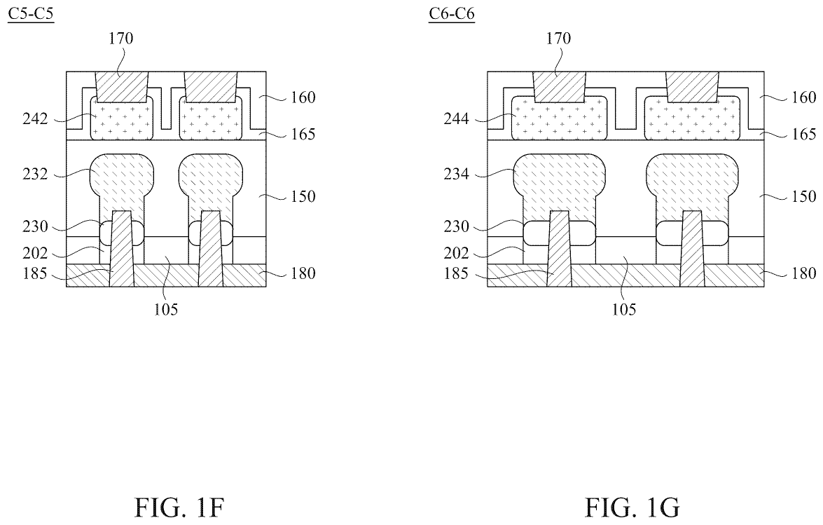

FIG. 1A illustrates a top view of an integrated circuit in accordance with some embodiments of the present disclosure. Shown there is an integrated circuit 10a. The integrated circuit 10a includes CFETs CF-11, CF-12, CF-13, CF-14, CF-21, and CF-22. In some embodiments, the CFETs CF-11, CF-12, CF-13, and CF-14 are arranged along the Y-direction, and the CFETs CF-21 and CF-22 are arranged along the Y-direction. In some embodiments, the first group of the CFETs CF-11, CF-12, CF-13, and CF-14 and the second group of the CFETs CF-21 and CF-22 are arranged along the X-direction that is substantially perpendicular to the Y-direction, and the first and second groups may include different numbers of CFETs. In some embodiments, the CFETs CF-11, CF-12, CF-13, and CF-14 may include a similar configuration, and the CFETs CF-21 and CF-22 may include a similar configuration, which will be discussed in more detail later.

The integrated circuit 10a includes semiconductor layers 112a, 112b, 112c, 112d, 114a, and 114b. In some embodiments, the semiconductor layers 112a, 112b, 112c, and 112d are arranged along the Y-direction and each may include a lengthwise direction along the X-direction. Similarly, the semiconductor layers 114a and 114b are arranged along the Y-direction and each may include a lengthwise direction along the X-direction. In some embodiments, in the top view of FIG. 1A, the semiconductor layers 114a may be partially aligned with the semiconductor layers 112a and 112b along the X-direction, and the semiconductor layers 114b may be partially aligned with the semiconductor layers 112c and 112d along the X-direction.

In some embodiments, the semiconductor layers 112a, 112b, 112c, 112d, 114a, and 114b each may include a semiconductor strip over a substrate, and a plurality of semiconductor sheets vertically stacked one above another over the semiconductor strip, which will be discussed in more detail later.

The semiconductor layers 112a, 112b, 112c, and 112d may include a same width along the Y-direction. For example, each of the semiconductor layers 112a, 112b, 112c, and 112d may include a width W1 along the Y-direction. On the other hand, the semiconductor layers 114a and 114b may include a same width along the Y-direction. For example, each of the semiconductor layers 114a and 114b may include a width W2 along the Y-direction. The width W2 is larger than the width W1. That is, the semiconductor layers 114a and 114b are wider than the semiconductor layers 112a, 112b, 112c, and 112d along the Y-direction. In some embodiments, the width W2 is larger than the width W1, and the width W2 is substantially the same as n times of the width W1. That is, the relationship between the width W2 and the width W1 can be expressed as W2=n*W1, where n is a positive integer. In some embodiments, n is in a range from 2 to 6.

In some embodiments, the distance between the semiconductor layers 112a and 112b, the distance between the semiconductor layers 112b and 112c, and the distance between the semiconductor layers 112c and 112d may be the same along the Y-direction, the distances can be referred to distances S1. On the other hand, the semiconductor layers 114a and 114b may include a distance S2 therebetween, in which the distance S2 may be larger than the distance S1.

In some embodiments, the sum of the width W2 and the distance S2 may be substantially the same as two times the sum of the width W1 and the distance S1. That is, the relationship among the widths W1 and W2 and the distances S1 and S2 can be expressed as W2+S2=2*(W1+S1). That is, the gate pitch of the second group of the CFETs CF-21 to CF-22 may be twice the gate pitch of the first group of the CFETs CF-11 to CF-14. In some embodiment where the integrated circuit 10a satisfy W2+S2=2*(W1+S1) and W2=2*W1, the distances S1 and S2 may satisfy S2=2*S1. That is, when the width W2 is substantially the same as two times the width W1, the distance S2 is substantially the same as two times the distance S1.

The integrated circuit 10a further includes gate structures 120a, 120b, 120c, 120d, and 120e. In some embodiments, the gate structures 120a, 120b, 120c, 120d, and 120e are arranged along the X-direction and each may include a lengthwise direction along the Y-direction. In some embodiments, the gate structures 120a and 120b may cross the semiconductor layers 112a, 112b, 112c, and 112d, and the gate structures 120d and 120e may cross the semiconductor layers 114a and 114b, respectively. In some embodiments, the gate structures 120a, 120b, 120c, 120d, and 120e may include substantially a same width along the X-direction.

In some embodiments, the gate structure 120a, the semiconductor layers 112a, and source/drain regions (not shown in FIG. 1A) on opposite sides of the semiconductor layers 112a may collectively function as the CFET CF-11. The gate structure 120a, the semiconductor layers 112b, and source/drain regions (not shown in FIG. 1A) on opposite sides of the semiconductor layers 112b may collectively function as the CFET CF-12. The gate structure 120a, the semiconductor layers 112c, and source/drain regions (not shown in FIG. 1A) on opposite sides of the semiconductor layers 112c may collectively function as the CFET CF-13. The gate structure 120a, the semiconductor layers 112d, and source/drain regions (not shown in FIG. 1A) on opposite sides of the semiconductor layers 112d may collectively function as the CFET CF-14. The gate structure 120d, the semiconductor layers 114a, and source/drain regions (not shown in FIG. 1A) on opposite sides of the semiconductor layers 114a may collectively function as the CFET CF-21. The gate structure 120d, the semiconductor layers 114b, and source/drain regions (not shown in FIG. 1A) on opposite sides of the semiconductor layers 114b may collectively function as the CFET CF-22.

The integrated circuit 10a further includes dielectric gates 125a and 125b. In some embodiments, the dielectric gates 125a and 125b are arranged along the X-direction and each may include a lengthwise direction along the Y-direction. In some embodiments, the dielectric gates 125a and 125b may include substantially a same profile as the gate structures 120a to 120e. In some embodiments, the dielectric gate 125a is between the gate structure 120b and the gate structure 120c, and the dielectric gate 125b is between the gate structure 120d and the gate structure 120c.

The integrated circuit 10a further includes jog regions 115a and 115b. In some embodiments, the jog region 115a may be a structure that connects the semiconductor layers 112a and 112b to the semiconductor layers 114a, and will be cut by the dielectric gates 125a and 125b during the manufacturing process. As a result, the jog region 115a may be in contact with both the dielectric gates 125a and 125b and may include a varying width. For example, the jog region 115a may include two sidewalls interfacing with the dielectric gate 125a, and the two sidewalls each may include a width that is substantially equal to the width W1 of the semiconductor layers 112a and 112b. The jog region 115a may include a sidewall interfacing with the dielectric gate 125b, and the sidewall may include a width that is substantially equal to the width W2 of the semiconductor layers 114a. In some embodiment, the term “jog region” may also be referred to as “transition region”.

On the other hand, the jog region 115b may be a structure that connects the semiconductor layers 112c and 112d to the semiconductor layers 114b, and will be cut by the dielectric gates 125a and 125b during the manufacturing process. As a result, the jog region 115b may be in contact with both the dielectric gates 125a and 125b and may include a varying width. For example, the jog region 115b may include two sidewalls interfacing with the dielectric gate 125a, and the two sidewalls each may include a width that is substantially equal to the width W1 of the semiconductor layers 112c and 112d. The jog region 115b may include a sidewall interfacing with the dielectric gate 125b, and the sidewall may include a width that is substantially equal to the width W2 of the semiconductor layers 114b.

FIGS. 1B to 1G illustrate cross-sectional views of an integrated circuit in accordance with some embodiments of the present disclosure. Specifically, FIGS. 1B, 1C, 1D, 1E, 1F, and 1G are cross-sectional views along lines C1-C1, C2-C2, C3-C3, C4-C4, C5-C5, and C6-C6 of FIG. 1A, respectively. More specifically, FIGS. 1B to 1G illustrate cross-sectional views of the CFETs CF-11 and CF-21 of FIG. 1A. It is noted that some elements of FIGS. 1B to 1G has been discussed in FIG. 1A, such elements will be labeled the same and relevant details will not be repeated for brevity.

Reference is made to FIGS. 1B, 1D, and 1F. With respect to the CFET CF-11, the CFET CF-11 may include a semiconductor strip 202, semiconductor sheets 212 over the semiconductor strip 202, and semiconductor sheets 213 over the semiconductor sheets 212. The semiconductor strip 202 and the semiconductor sheets 212 and 213 are represented by the semiconductor layers 112a as shown in FIG. 1A. That is, the semiconductor strip 202 and the semiconductor sheets 212 and 213 may include similar top profile as the semiconductor layers 112a of FIG. 1A. However, in other embodiments, the semiconductor sheets 212 and 213 may also include different widths. In some embodiments, the semiconductor sheets 212 may serve as channel layers of a bottom transistor of the CFET CF-11, and the semiconductor sheets 213 may serve as channel layers of a top transistor of the CFET CF-11.

The thickness of the semiconductor sheets 212 may be different from the semiconductor sheets 213. For example, the semiconductor sheets 212 may be thicker than the semiconductor sheets 213 in some embodiments, while the semiconductor sheets 212 may be thinner than the semiconductor sheets 213 in other embodiments. In some embodiments, the thickness difference between the semiconductor sheets 212 and 213 may be in a range from about 0.5 nm to about 5 nm.

The space between two adjacent semiconductor sheets 212 may be different from the space between two adjacent semiconductor sheets 213. For example, space between two adjacent semiconductor sheets 212 may be greater than the space between two adjacent semiconductor sheets 213, while the space between two adjacent semiconductor sheets 212 may be less than the space between two adjacent semiconductor sheets 213 in other embodiments. In some embodiments, the space difference may be in a range from about 0.5 nm to about 5 nm.

It is noted that the numbers of the semiconductor sheets 212 and 213 are merely used to explain, the disclosure is not limited thereto. In other embodiments, more or less semiconductor sheets 212 and 213 may also be applied. For example, the number of the semiconductor sheets 212 or the semiconductor sheets 213 can be 1, 2, 3, 4, or more. In some embodiments, the number of the semiconductor sheets 212 can be different from the number of the semiconductor sheets 213.

In some embodiments, the semiconductor strip 202 and the semiconductor sheets 212 and 213 may include semiconductor material. Exemplary semiconductor material includes crystalline silicon, but may also be other semiconductor materials such as germanium, silicon-germanium, compound semiconductors (e.g., GaAs, AlAs, InAs, GaN, AlN, and the like), or their alloys (e.g., GaₓAl₁₋ₓAs, GaₓAl₁₋ₓN, InₓGa₁₋ₓAs and the like). In some embodiments, the semiconductor sheets 212 and 213 may be made of a same material, or may be made of different materials.

The CFET CF-11 further includes a gate structure 120a crossing the semiconductor strip 202 and wrapping around each of the semiconductor sheets 212 and 213. In some embodiments, the gate structure 120a may include a gate dielectric 222 extending along surfaces of the semiconductor strip 202 and the semiconductor sheets 212 and 213. The gate structure 120a further includes a bottom electrode 224 and a top electrode 226 over the bottom electrode 224. The bottom electrode 224 may cross the semiconductor strip 202 and wrap around the semiconductor sheets 212, and the top electrode 226 may wrap around the semiconductor sheets 213. In some embodiments, the interface between the top electrode 226 and the bottom electrode 224 is between the semiconductor sheets 212 and the semiconductor sheets 213. In some embodiments, the bottom electrode 224 may serve as gate electrode of the bottom transistor of the CFET CF-11, and the top electrode 226 may serve as gate electrode of a top transistor of the CFET CF-11.

The CFET CF-11 further includes source/drain regions 232 in contact with opposite ends of each of the semiconductor sheets 212, and source/drain regions 242 in contact with opposite ends of each of the semiconductor sheets 213. The source/drain regions 242 are at a level above the source/drain regions 232, and each of the source/drain regions 242 is vertically above a respective one of the source/drain regions 232. In some embodiments, the source/drain regions 232 may include opposite conductivity than the source/drain regions 242. For example, if the source/drain regions 232 are N-type source/drain regions, the source/drain regions 242 are P-type source/drain regions. Similarly, if the source/drain regions 232 are P-type source/drain regions, the source/drain regions 242 are N-type source/drain regions.

The CFET CF-11 may include a bottom transistor and a top transistor above the bottom transistor. The semiconductor sheets 212, the gate dielectric 222, the bottom electrode 224, and the source/drain regions 232 may collectively serve as the bottom transistor. On the other hand, the semiconductor sheets 213, the gate dielectric 222, the top electrode 226, and the source/drain regions 242 may collectively serve as the top transistor. In some embodiments, the top transistor and the bottom transistor may include opposite conductivity types. For example, when the bottom transistor is an N-type transistor, the top transistor is a P-type type transistor. Similarly, when the bottom transistor is a P-type transistor, the top transistor is an N-type type transistor.

It is noted that the CFETs CF-12, CF-13, and CF-14 of FIG. 1A may include similar configuration as the CFET CF-11 as discussed above. For example, each of the CFETs CF-13, and CF-14 may also include a semiconductor strip 202, semiconductor sheets 212 and 213, gate structure 120a, and source/drain regions 232 and 242. In some embodiments, the semiconductor strip 202 and the semiconductor sheets 212 and 213 of the CFET CF-12 may include substantially the same top profile as the semiconductor layers 112b of FIG. 1A. Similarly, the semiconductor strip 202 and the semiconductor sheets 212 and 213 of the CFET CF-13 may include substantially the same top profile as the semiconductor layers 112c of FIG. 1A. Similarly, the semiconductor strip 202 and the semiconductor sheets 212 and 213 of the CFET CF-14 may include substantially the same top profile as the semiconductor layers 112c of FIG. 1A.

Reference is made to FIGS. 1C, 1E, and 1G. With respect to the CFET CF-21, the CFET CF-21 may include a semiconductor strip 204, semiconductor sheets 214 over the semiconductor strip 204, and semiconductor sheets 215 over the semiconductor sheets 214. The semiconductor strip 204 and the semiconductor sheets 214 and 215 are represented by the semiconductor layers 114a as shown in FIG. 1A. That is, the semiconductor strip 204 and the semiconductor sheets 214 and 215 may include similar top profile as the semiconductor layers 114a of FIG. 1A. However, in other embodiments, the semiconductor sheets 214 and 215 may also include different widths. In some embodiments, the semiconductor sheets 214 may serve as channel layers of a bottom transistor of the CFET CF-21, and the semiconductor sheets 215 may serve as channel layers of a top transistor of the CFET CF-21.

The thickness of the semiconductor sheets 214 may be different from the semiconductor sheets 215. For example, the semiconductor sheets 214 may be thicker than the semiconductor sheets 215 in some embodiments, while the semiconductor sheets 214 may be thinner than the semiconductor sheets 215 in other embodiments. In some embodiments, the thickness difference between the semiconductor sheets 214 and 215 may be in a range from about 0.5 nm to about 5 nm.

The space between two adjacent semiconductor sheets 214 may be different from the space between two adjacent semiconductor sheets 215. For example, space between two adjacent semiconductor sheets 214 may be greater than the space between two adjacent semiconductor sheets 215, while the space between two adjacent semiconductor sheets 214 may be less than the space between two adjacent semiconductor sheets 215 in other embodiments. In some embodiments, the space difference may be in a range from about 0.5 nm to about 5 nm.

It is noted that the numbers of the semiconductor sheets 214 and 215 are merely used to explain, the disclosure is not limited thereto. In other embodiments, more or less semiconductor sheets 214 and 215 may also be applied. For example, the number of the semiconductor sheets 214 or the semiconductor sheets 215 can be 1, 2, 3, 4, or more. In some embodiments, the number of the semiconductor sheets 214 can be different from the number of the semiconductor sheets 215.

In some embodiments, the semiconductor strip 204 and the semiconductor sheets 214 and 215 may include semiconductor material. Exemplary semiconductor material includes crystalline silicon, but may also be other semiconductor materials such as germanium, silicon-germanium alloys, compound semiconductors (e.g., GaAs, AlAs, InAs, GaN, AlN, and the like), or their alloys (e.g., GaₓAl₁₋ₓAs, GaₓAl₁₋ₓN, InₓGa₁₋ₓAs and the like). In some embodiments, the semiconductor sheets 214 and 215 may be made of a same material, or may be made of different materials.

The CFET CF-21 further includes a gate structure 120d crossing the semiconductor strip 204 and wrapping around each of the semiconductor sheets 214 and 215. In some embodiments, the gate structure 120d may include a gate dielectric 222 extending along surfaces of the semiconductor strip 204 and the semiconductor sheets 214 and 215. The gate structure 120d further includes a bottom electrode 224 and a top electrode 226 over the bottom electrode 224. The bottom electrode 224 may cross the semiconductor strip 204 and wrap around the semiconductor sheets 214, and the top electrode 226 may wrap around the semiconductor sheets 215. In some embodiments, the interface between the top electrode 226 and the bottom electrode 224 is between the semiconductor sheets 214 and the semiconductor sheets 215. In some embodiments, the bottom electrode 224 may serve as gate electrode of the bottom transistor of the CFET CF-21, and the top electrode 226 may serve as gate electrode of a top transistor of the CFET CF-21.

The CFET CF-21 further includes source/drain regions 234 in contact with opposite ends of each of the semiconductor sheets 214, and source/drain regions 244 in contact with opposite ends of each of the semiconductor sheets 215. The source/drain regions 244 are at a level above the source/drain regions 234, and each of the source/drain regions 244 is vertically above a respective one of the source/drain regions 234. In some embodiments, the source/drain regions 234 may include opposite conductivity than the source/drain regions 244. For example, if the source/drain regions 234 are N-type source/drain regions, the source/drain regions 244 are P-type source/drain regions. Similarly, if the source/drain regions 234 are P-type source/drain regions, the source/drain regions 244 are N-type source/drain regions.

The CFET CF-21 may include a bottom transistor and a top transistor above the bottom transistor. The semiconductor sheets 214, the gate dielectric 222, the bottom electrode 224, and the source/drain regions 234 may collectively serve as the bottom transistor. On the other hand, the semiconductor sheets 215, the gate dielectric 222, the top electrode 226, and the source/drain regions 244 may collectively serve as the top transistor. In some embodiments, the top transistor and the bottom transistor may include opposite conductivity types. For example, when the bottom transistor is an N-type transistor, the top transistor is a P-type type transistor. Similarly, when the bottom transistor is a P-type transistor, the top transistor is an N-type type transistor.

It is noted that the CFET CF-22 of FIG. 1A may include similar configuration as the CFET CF-21 as discussed above. For example, the CFET CF-22 may also include a semiconductor strip 204, semiconductor sheets 214 and 215, gate structure 120d, and source/drain regions 234 and 244. In some embodiments, the semiconductor strip 204 and the semiconductor sheets 214 and 215 of the CFET CF-22 may include substantially the same top profile as the semiconductor layers 114b of FIG. 1A.

Reference is made to FIGS. 1A, 1B, 1C, 1D, and 1E. Based on the above discussion, it can be understood that the semiconductor sheets 214 and 215 are wider than the semiconductor sheets 213 and 214 along the Y-direction (see FIGS. 1A, 1D, and 1E. However, the semiconductor sheets 214 and 215 may include substantially a same width as the semiconductor sheets 213 and 214 along the X-direction.

Reference is made to FIGS. 1B to 1G. The integrated circuit 10a further includes isolation structures 105 laterally surrounding the semiconductor strips 202 and 204. In some embodiments, the isolation structures 105 may be shallow trench isolation (STI) structures, suitable isolation structures, combinations of the foregoing, or the like. In some embodiments, the isolation structures 105 may be made of oxide (e.g., silicon oxide), nitride (e.g., silicon nitride), or combinations thereof.

The integrated circuit 10a further includes spacers 135 on opposite sidewalls of each of the gate structures 120a and 120e, as shown in FIGS. 1B and 1C. The integrated circuit 10a further includes inner spacers 136 on opposite sidewalls of each of the gate structures 120a and 120e and vertically above or below the semiconductor sheets 212, 213, 214, and 215, respectively. In some embodiments, the spacers 135 and the inner spacers 136 may be formed of silicon oxide, silicon nitride, silicon oxynitride, combinations thereof.

The integrated circuit 10a further includes an interlayer dielectric (ILD) layer 150 over the isolation structures 105 and covering the source/drain regions 232 and 234. In some embodiments, the ILD layer 150 may include silicon oxide, silicon nitride, silicon oxynitride, tetraethoxysilane (TEOS), phosphosilicate glass (PSG), borophosphosilicate glass (BPSG), low-k dielectric material, and/or other suitable dielectric materials. Examples of low-k dielectric materials include, but are not limited to, fluorinated silica glass (FSG), carbon doped silicon oxide, amorphous fluorinated carbon, parylene, bis-benzocyclobutenes(BCB), or polyimide.

The integrated circuit 10a further includes a contact etch stop layer (CESL) 165 extending along surfaces of the ILD layer 150 and the source/drain regions 242 and 244, and an interlayer dielectric (ILD) layer 160 over the CESL 165. In some embodiments, the CESL 165 may be a dielectric layer including silicon nitride, silicon oxynitride or other suitable materials. The ILD layer 160 may include a similar material as the ILD layer 150, and thus relevant details will not be repeated for brevity.

The integrated circuit 10a further includes source/drain contacts 170 extending through the ILD layer 160 and the CESL 165 and electrically connected with the respective source/drain regions 234 and 244. In some embodiments, each of the source/drain contacts 170 may include a conductive plug and a barrier layer lining the conductive plug. In some embodiments, the barrier layer may include tantalum-based or titanium-based material, such as tantalum nitride (TaN), titanium nitride (TiN), titanium oxide (TiO), titanium (Ti), or the like. The conductive plug may include tungsten (W), copper (Cu), aluminum (Al), ruthenium (Ru), cobalt (Co), molybdenum (Mo), nickel (Ni), or other suitable conductive material.

The integrated circuit 10a further includes isolation layers 230 in contact with bottom surfaces of the source/drain regions 232 and 242, and may be in contact with top surfaces of the semiconductor strips 202 and 204. In some embodiments, the isolation layers 230 may include suitable dielectric material, such as SiN, SiO2, SiON, SiCN, SiCON, SiCO, High-K dielectric (HfO, AlO, etc.), the like, or combinations thereof.

The integrated circuit 10a further includes a dielectric layer 180 extending along bottom surfaces of the semiconductor strips 202 and 204, and the isolation structures 105. In some embodiments, the dielectric layer 180 may include suitable dielectric material such as silicon oxide, silicon nitride, silicon oxynitride or other suitable materials.

The integrated circuit 10a further includes source/drain contacts 185 extending through the dielectric layer 180, the respective semiconductor strips 202 and 204, the respective isolation layers 230, and electrically connected with the respective source/drain regions 232 and 242. In some embodiments, each of the source/drain contacts 185 may include a conductive plug and a barrier layer lining the conductive plug. In some embodiments, the barrier layer may include tantalum-based or titanium-based material, such as tantalum nitride (TaN), titanium nitride (TiN), titanium oxide (TiO), titanium (Ti), or the like. The conductive plug may include tungsten (W), copper (Cu), aluminum (Al), ruthenium (Ru), cobalt (Co), molybdenum (Mo), nickel (Ni), or other suitable conductive material.

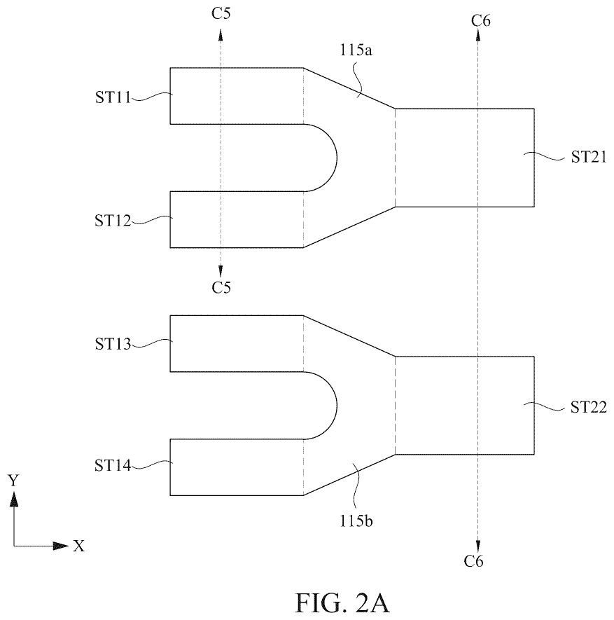

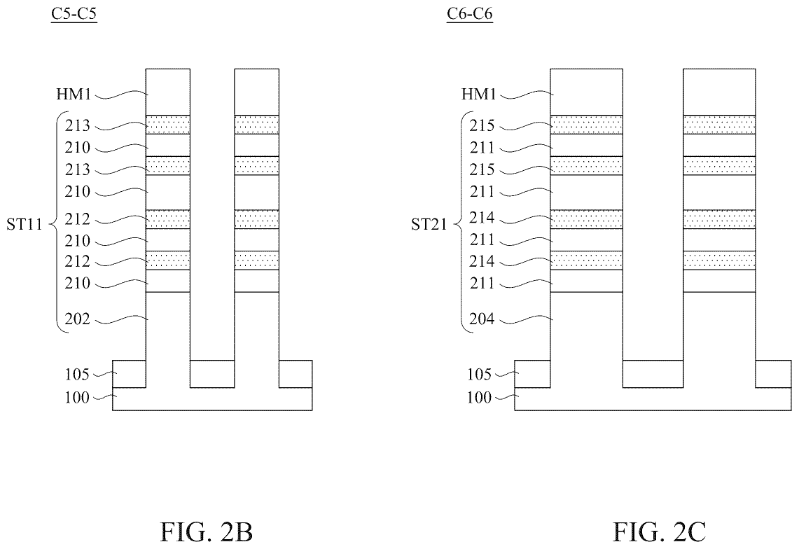

FIGS. 2A to 15D illustrate a method in various stages of forming a semiconductor device in accordance with some embodiments of the present disclosure. Specifically, FIGS. 2A to 15D illustrate a method for forming the integrated circuit 10a as discussed in FIGS. 1A to 1G. It is noted that some elements of FIGS. 2A to 15D may be similar to those described with respect to FIGS. 1A to 1G, such elements will be labeled the same, and relevant details will not be repeated for brevity.

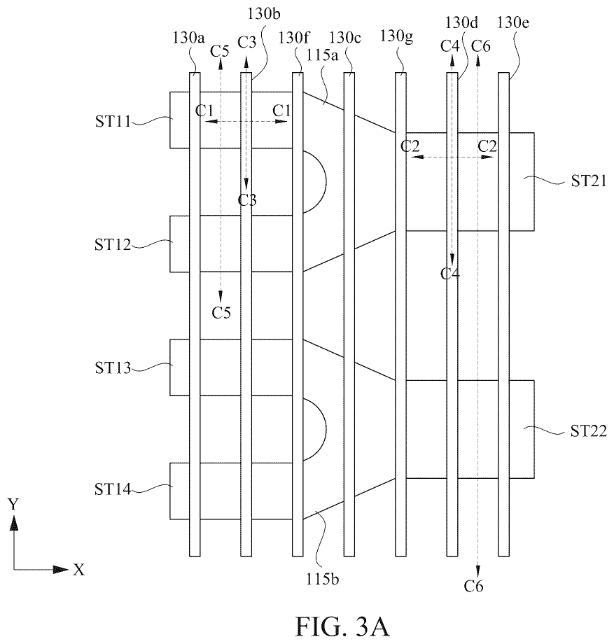

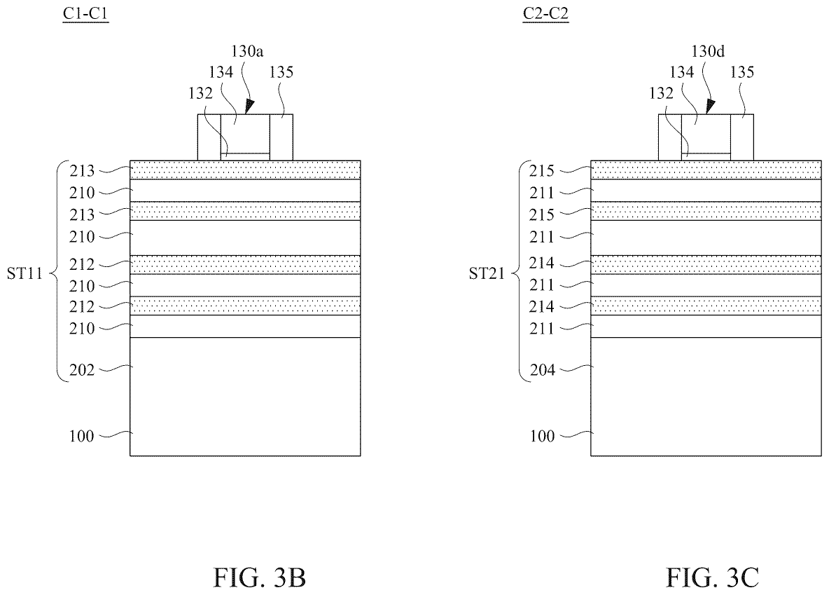

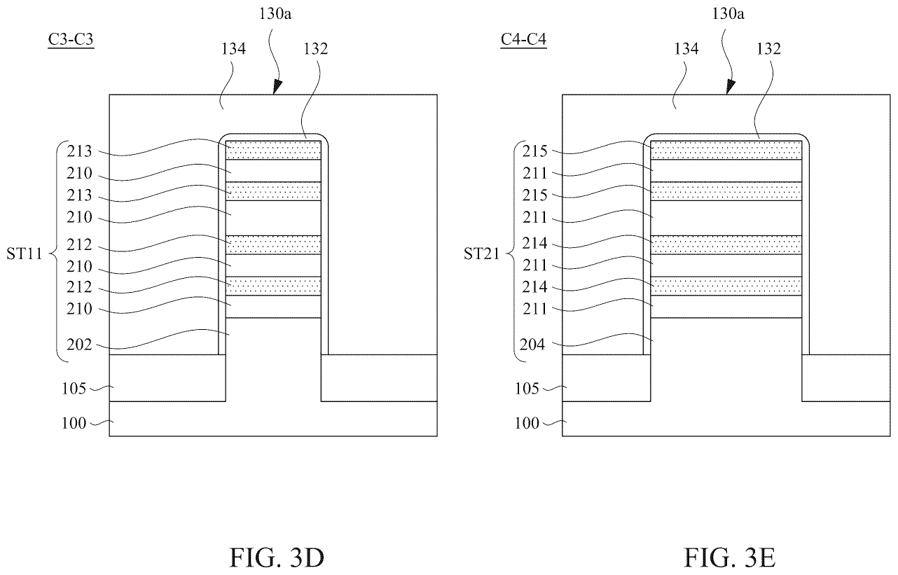

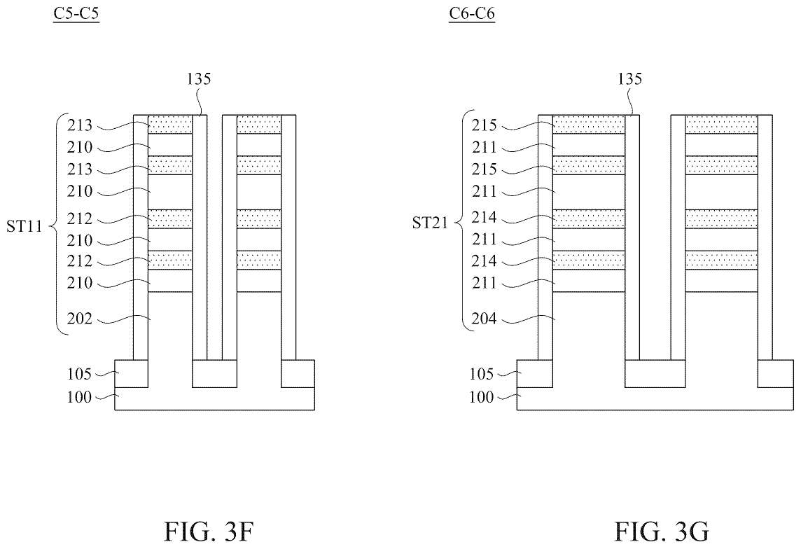

In greater detail, FIGS. 2A, 3A, 10A, and 14A illustrate top views that are the same as the top view of FIG. 1A. FIGS. 3B, 4A, 5A, 6A, 7A, 8A, 9A, 10B, 11A, 12A, 13A, 14B, and 15A are cross-sectional views that are the same as the top view of FIG. 1B. FIGS. 3C, 4B, 5B, 6B, 7B, 8B, 9B, 10C, 11B, 12B, 13B, 14C, and 15B are cross-sectional views that are the same as the top view of FIG. 1C. FIGS. 3D, 11C, 12C, 13C, and 14D are cross-sectional views that are the same as the top view of FIG. 1D. FIGS. 3E, 11D, 12D, 13D, and 14E are cross-sectional views that are the same as the top view of FIG. 1E. FIGS. 2B, 3F, 4C, 6C, 7C, 8C, 9C, 10D, and 15C are cross-sectional views that are the same as the top view of FIG. 1F. FIGS. 2C, 3G, 4D, 6D, 7D, 8D, 9D, 10E, and 15D are cross-sectional views that are the same as the top view of FIG. 1G.

Reference is made to FIGS. 2A, 2B, and 2C. Shown there is a substrate 100. Generally, the substrate 100 may include a bulk semiconductor substrate or a silicon-on-insulator (SOI) substrate. An SOI substrate includes an insulator layer below a thin semiconductor layer that is the active layer of the SOI substrate. The semiconductor of the active layer and the bulk semiconductor generally include the crystalline semiconductor material silicon, but may include one or more other semiconductor materials such as germanium, silicon-germanium alloys, compound semiconductors (e.g., GaAs, AlAs, InAs, GaN, AlN, and the like), or their alloys (e.g., GaₓAl₁₋ₓAs, GaₓAl₁₋ₓN, InₓGa₁₋ₓAs and the like), oxide semiconductors (e.g., ZnO, SnO₂, TiO₂, Ga₂O₃, and the like) or combinations thereof.

Stacks ST11, ST12, ST13, ST14, ST21, and ST22 are formed over the substrate 100. Specifically, each of the stacks ST11, ST12, ST13, ST14, ST21, and ST22 may include a semiconductor strip and alternating semiconductor layers and sacrificial layers over the semiconductor strip. For example, in FIG. 2B, each of the stacks ST11 and ST12 may include a semiconductor strip 202, and alternating semiconductor layers (e.g., semiconductor sheets 212 and 213) and sacrificial layers 210 over the semiconductor strip 202. Similarly, in FIG. 2C, each of the stacks ST11 and ST12 may include a semiconductor strip 204, and alternating semiconductor layers (e.g., semiconductor sheets 214 and 215) and sacrificial layers 211 over the semiconductor strip 204. It is noted that each layer of the stack ST11 may include a similar top profile as the semiconductor layers 112a of FIG. 1A, each layer of the stack ST12 may include a similar top profile as the semiconductor layers 112b of FIG. 1A, each layer of the stack ST13 may include a similar top profile as the semiconductor layers 112c of FIG. 1A, each layer of the stack ST21 may include a similar top profile as the semiconductor layers 114a of FIG. 1A, and each layer of the stack ST22 may include a similar top profile as the semiconductor layers 114b of FIG. 1A.

The stacks ST11, ST12, ST13, ST14, ST21, and ST22 can be formed by, for example, alternating depositing semiconductor materials and sacrificial materials over the substrate 100, and then forming a hard mask layer HM1 over the topmost semiconductor layer, and then patterning the hard mask layer HM1, the semiconductor layers, the sacrificial layers, and the substrate 100 to form the stacks ST11, ST12, ST13, ST14, ST21, and ST22.

In some embodiments, patterning the hard mask layer HM1, the semiconductor layers, the sacrificial layers, and the substrate 100 further includes forming jog regions 115a and 115b. The jog region 115a may include the same layers as the stacks ST11, SY12, and ST21, and the jog region 115b may include the same layers as the stacks ST13, ST14, and ST22. For example, each of the jog regions 115a and 115b may include a semiconductor strip protruding from the top surface of the substrate 100, and alternating semiconductor layers and sacrificial layers. In some embodiments, each layer of the jog region 115a may be in contact with a corresponding layer of the stack ST11, a corresponding layer of the stack ST12, and a corresponding layer of the stack ST21. Similarly, each layer of the jog region 115b may be in contact with a corresponding layer of the stack ST13, and a corresponding layer of the stack ST14, and a corresponding layer of the stack ST22.

In some embodiments, the semiconductor layers (e.g., semiconductor sheets 212, 213, 214 and 215) may be made of pure silicon layers that are free of germanium. In some embodiments, the semiconductor layers may also be substantially pure silicon layers, for example, with a germanium percentage lower than about 1 percent. The sacrificial layers 210 and 211 may be made of semiconductor materials such as silicon germanium. For example, the germanium percentage (atomic percentage concentration) of the sacrificial layers 210 and 211 may be in a range from about 20 percent and about 60 percent. In some embodiments, the semiconductor layers and the sacrificial layers may be deposited using suitable deposition process, such as selective epitaxial growth (SEG), chemical vapor deposition (CVD), molecular beam epitaxy (MBE), or other suitable process(es). In some embodiments, the sacrificial layers 210 and 211 may be removed during a replacement gate (RPG) process.

After the stacks ST11, ST12, ST13, ST14, ST21, and ST22 are formed, isolation structures 105 are formed over the substrate 100 and laterally surrounding the semiconductor strips 202 and 204. In some embodiments, the isolation structures 105 can be formed by, for example, depositing a dielectric material blanker over the substrate 100, and then etching back the dielectric material to lower the top surface of the dielectric material to a desired position.

Reference is made to FIGS. 3A to 3G. Dummy gate structures 130a, 130b, 130c, 130d, 130e, 130f, and 130g are formed over the substrate 100 and crossing the stacks ST11, ST12, ST13, ST14, ST21, and ST22, and the jog regions 115a and 115b, respectively. In greater detail, the dummy gate structures 130a and 130b may cross the stacks ST11, ST12, ST13, and ST14, and the dummy gate structures 130d and 130e may cross the stacks ST21 and ST22, respectively. The dummy gate structure 130c may cross the jog regions 115a and 115b. The dummy gate structure 130f may cross the stacks ST11, ST12, ST13, and ST14, and the jog regions 115a and 115b. The dummy gate structure 130g may cross the stacks ST21 and ST22, and the jog regions 115a and 115b. In some embodiments, the hard mask layer HM1 may be removed prior to forming the dummy gate structures 130a to 130g.

In some embodiments, each of the dummy gate structures 130 includes a dummy gate dielectric 132 and a dummy gate electrode 134 over the dummy gate dielectric 132. The dummy gate dielectric 132 may be, for example, silicon oxide, silicon nitride, a combination thereof, or the like, and may be deposited or thermally grown according to acceptable techniques. The dummy gate electrode 134 may be a conductive or non-conductive material and may be selected from a group including amorphous silicon, polycrystalline-silicon (polysilicon), poly-crystalline silicon-germanium (poly-SiGe), metallic nitrides, metallic silicides, metallic oxides, and metals.

Spacers 135 are formed on opposite sidewalls of each of the dummy gate structures 130a to 130g, and on opposite sidewalls of the stacks ST11 to ST22. In some embodiments, the spacers 135 may be formed of silicon oxide, silicon nitride, silicon oxynitride, combinations thereof. In some embodiments, the spacers 135 may be formed by, for example, depositing a spacer layer blanket over the substrate, and then performing an anisotropic etching process to remove horizontal portions of the spacer layer, such that vertical portions of the spacer layer remain on sidewalls of the dummy gate structures 130a to 130g and on sidewalls of the stacks ST12 to ST22. In some embodiments, the remaining vertical portions of the spacer layer can be referred to as the spacers 135. The spacer layer may be deposited using techniques such CVD, ALD, or the like.

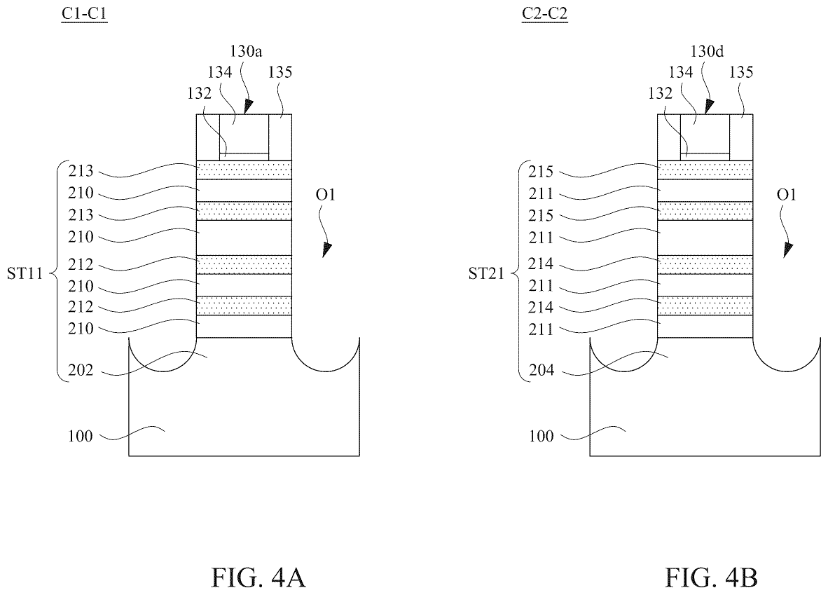

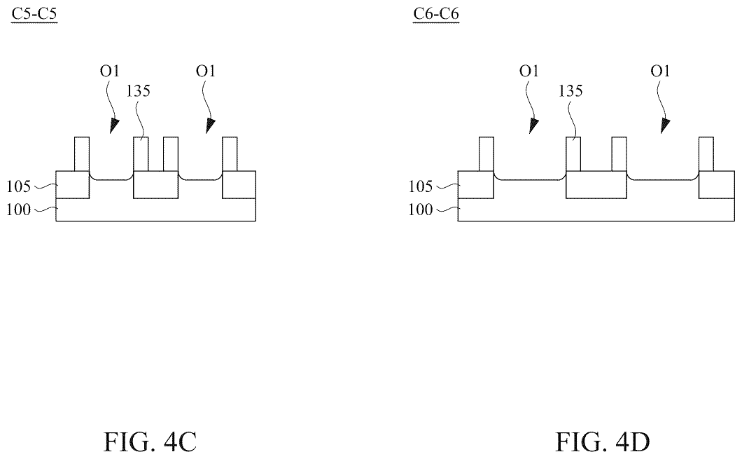

Reference is made to FIGS. 4A to 4D. An etching process may be performed by using the dummy gate structures 130a to 130g and the spacers 135 as an etch mask, so as to form source/drain openings O1 in the stacks ST11 to ST22, respectively. In some embodiments, the etching process may be wet etch, dry etch, or combinations thereof.

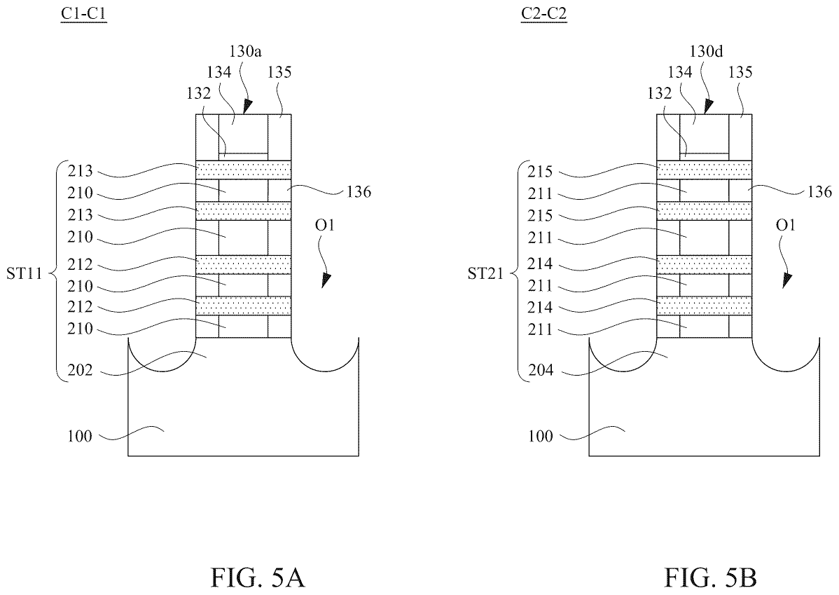

Reference is made to FIGS. 5A and 5B. After the source/drain openings O1 are formed, the sacrificial layers 210 and 211 are laterally etched to form sidewall recesses. In some embodiments, the sidewalls of the sacrificial layers 210 and 211 may be etched using isotropic etching processes, such as wet etching or the like.

Then, inner spacers 136 are formed in the sidewall recesses on opposite ends of each of the sacrificial layers 210 and 211. In some embodiments, the inner spacers 136 may be formed by, for example, depositing an inner spacer layer blanket over the substrate 100 and filling the sidewall recesses, and then performing an anisotropic etching to remove portions of the inner spacer layer outside the sidewall recesses, leaving the remaining portions of the inner spacer layer in the sidewall recesses as the inner spacers 136. The inner spacers 136 may be deposited by a conformal deposition process, such as CVD, ALD, or the like.

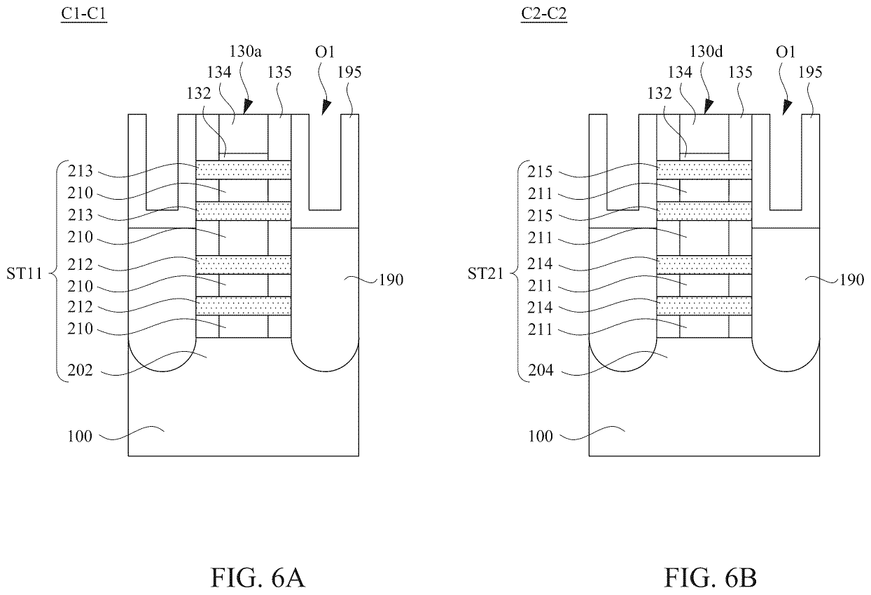

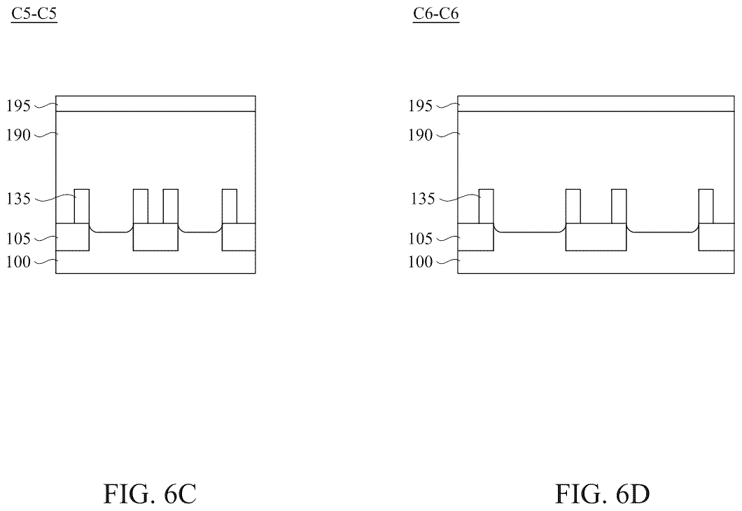

Reference is made to FIGS. 6A to 6D. Dummy materials 190 are formed in the source/drain openings O1. In greater detail, the dummy materials 190 may be formed at lower portions of the source/drain openings O1, such that the top surfaces of the dummy materials 190 may be lower than the bottommost semiconductor sheets 213 and 215. As a result, the sidewalls of the semiconductor sheets 213 and 215 may be exposed through the upper portions of the source/drain openings O1 once the dummy materials 190 are formed. In some embodiments, the dummy materials 190 may be formed by, for example, depositing a dielectric material filling the source/drain openings O1, and then etching back the dielectric material to lower the top surface of the dielectric material to a desired position. In some embodiments, the dummy materials 190 may be made of SiOC, SiOCN, or other suitable material.

Afterwards, liners 195 are formed lining the source/drain openings O1, so as to cover the sidewall surfaces of the semiconductor sheets 213 and 215 and top surfaces of the dummy materials 190. In some embodiments, the liners 195 may be made of SiN, metal oxide, or other suitable material. In some embodiments, the liners 195 may be made of a different material than the dummy materials 190.

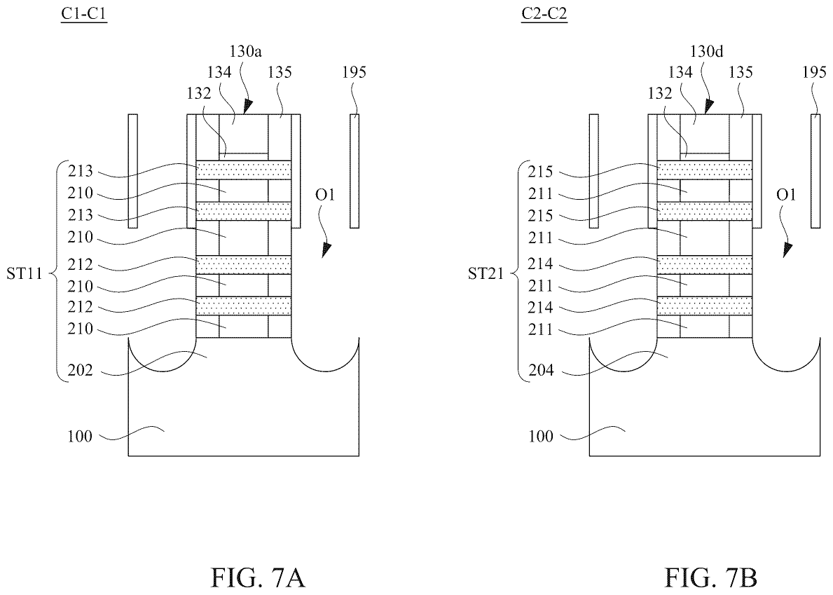

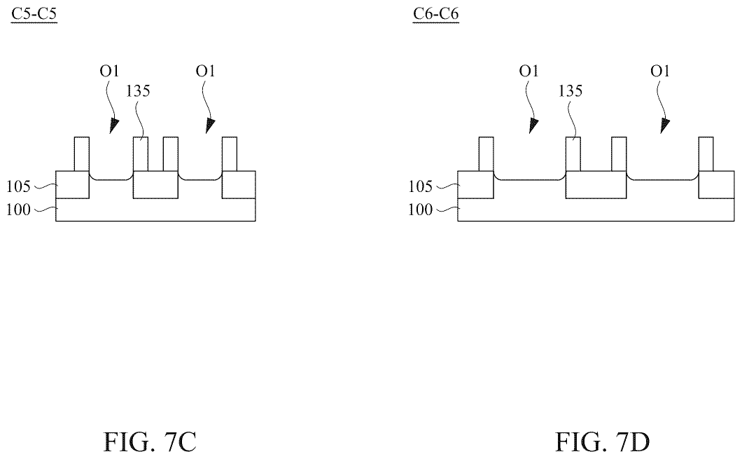

Reference is made to FIGS. 7A to 7D. An anisotropic etching process is performed to remove horizontal portions of the liners 195 to expose the top surfaces of the dummy materials 190 (see FIGS. 6A to 6D). On the other hand, vertical portions of the liners 195 remain on sidewalls of the semiconductor sheets 213 and 215, and sidewalls of the spacers 135.

Afterwards, the dummy materials 190 are removed by suitable etching process, so as to expose the sidewalls of the semiconductor sheets 212 and 214 through the lower portions of the source/drain openings O1. In some embodiments, the liners 195 may include a higher etching resistance to the etching process than the dummy materials 190, and thus the liners 195 may remain after the dummy materials 190 are removed.

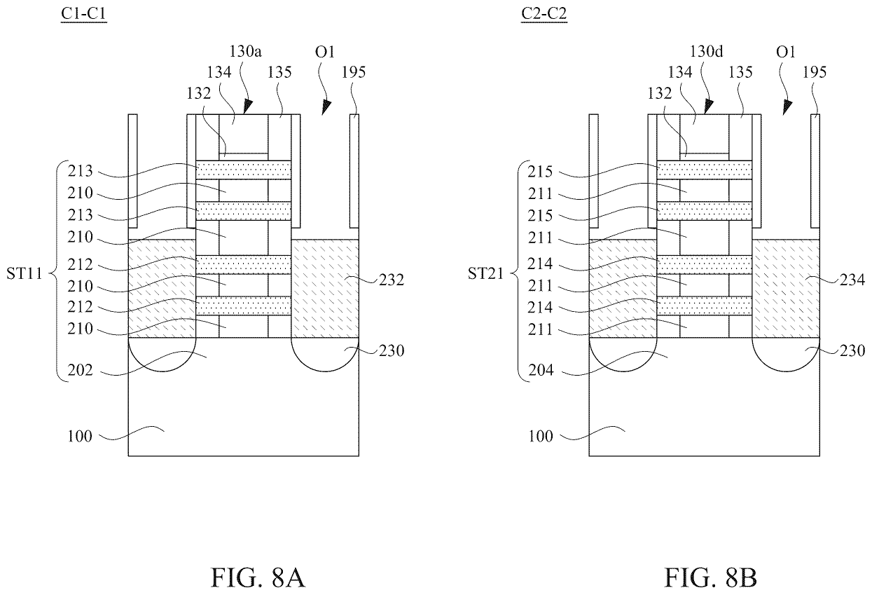

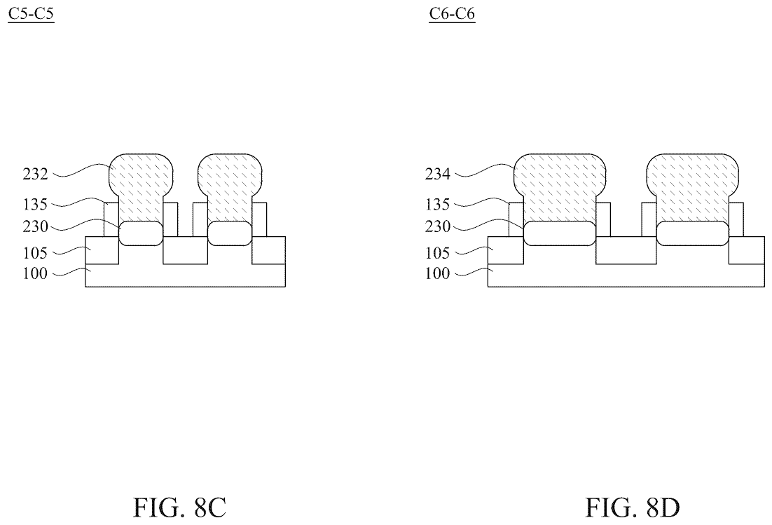

Reference is made to FIGS. 8A to 8D. Isolation layers 230 are formed in the bottom portions of the source/drain openings O1, and source/drain regions 232 and 234 are then formed in the openings O1, respectively. In greater detail, the source/drain regions 232 are formed on opposite sides of the semiconductor sheets 212, and the source/drain regions 234 are formed on opposite sides of the semiconductor sheets 214. The isolation layers 230 may be formed be depositing a dielectric material in the source/drain openings O1, and then etching back the dielectric material. The source/drain regions 232 and 242 may be formed by suitable deposition process, such as a selective epitaxial growth (SEG) process. In some embodiments, an implantation process may be performed to the source/drain regions 232 and 242. For example, the implantation process may include p-type dopants or n-type dopants.

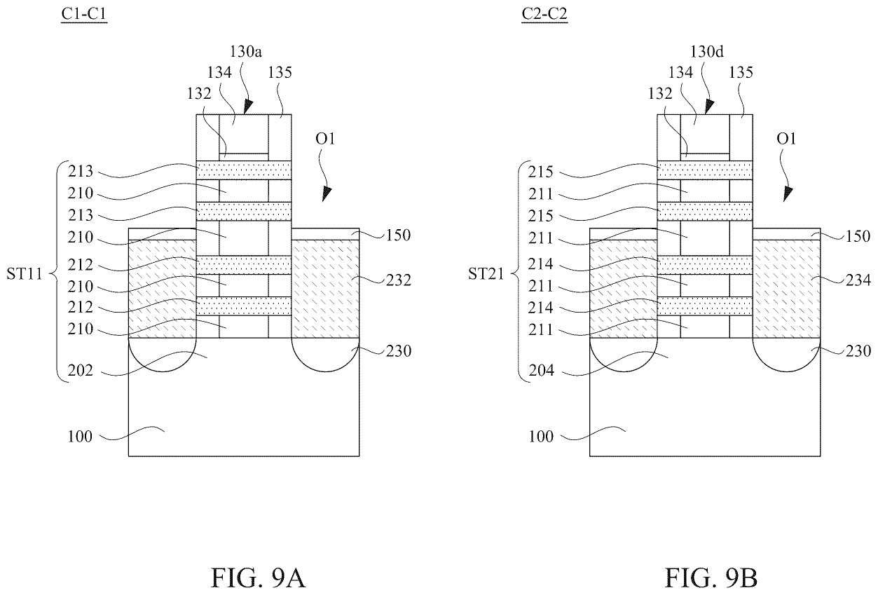

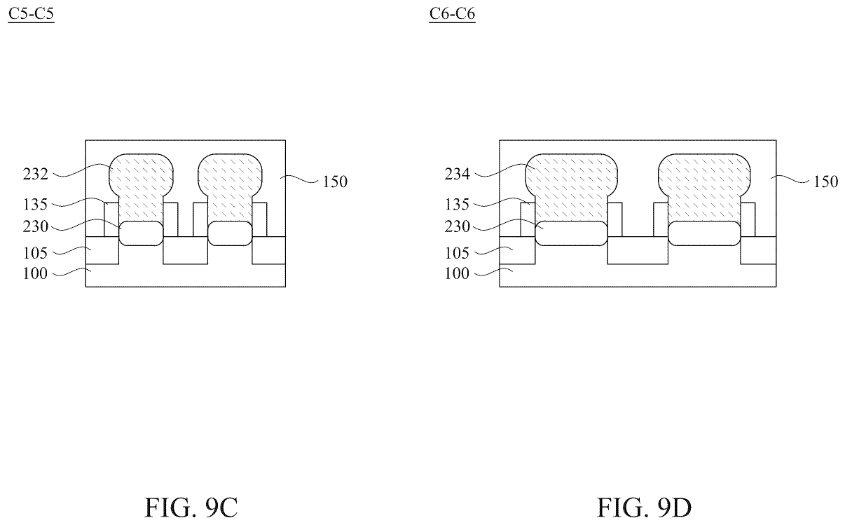

Reference is made to FIGS. 9A to 9D. Once the source/drain regions 232 and 242 are formed, the liners 195 are removed using suitable etching process, so as to expose sidewalls of the semiconductor sheets 213 and 215. Afterwards, an interlayer dielectric (ILD) layer 150 is formed over the source/drain regions 232 and 234 using suitable deposition process. Then, an etching back process is performed to lower top surface of the ILD layer 150, such that sidewalls of the semiconductor sheets 213 and 215 are exposed through the source/drain openings O1.

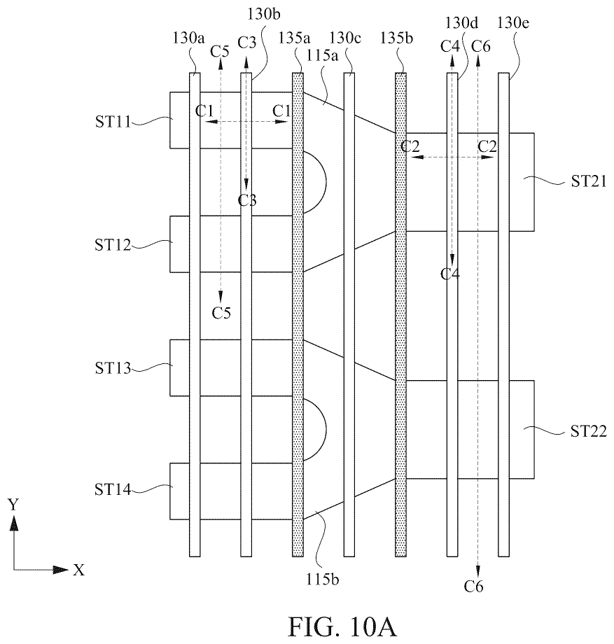

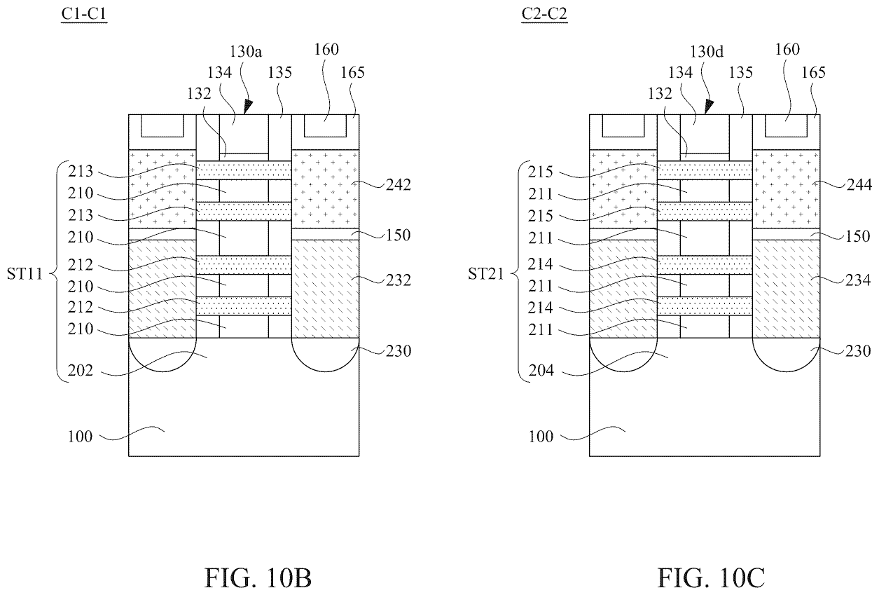

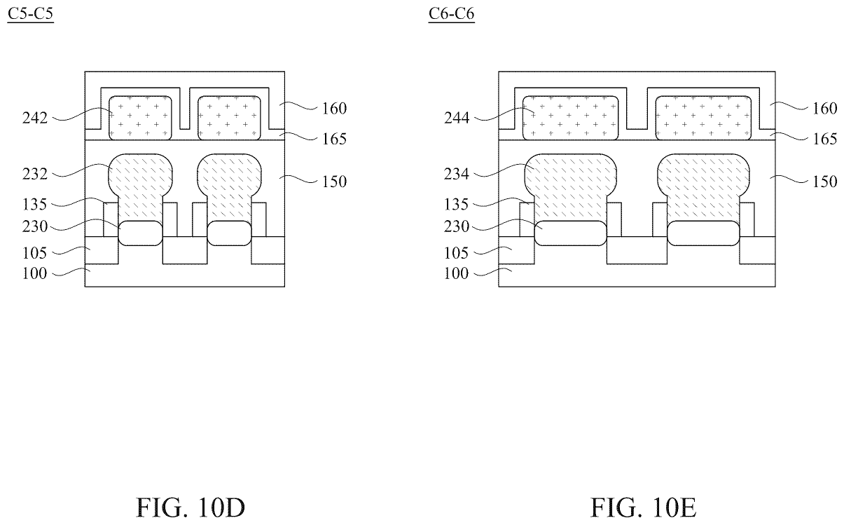

Reference is made to FIGS. 10A to 10E. Source/drain regions 234 and 244 are formed in top portions of the source/drain openings O1. In greater detail, the source/drain regions 234 are formed on opposite sides of the semiconductor sheets 213, and the source/drain regions 244 are formed on opposite sides of the semiconductor sheets 215. In some embodiments, the source/drain regions 234 and 244 may be formed by a selective epitaxial growth (SEG) process. In some embodiments, an implantation process may be performed to the source/drain regions 234 and 244. For example, the implantation process may include n-type dopants or p-type dopants.

A contact etch stop layer (CESL) 165 is formed covering the source/drain regions 234 and 244. Afterwards, an interlayer dielectric (ILD) layer 160 is formed over the CESL 165. Then, a planarization process, such as CMP, is performed to remove excess materials of the CESL 165 and the ILD layer 160 until the dummy gate structures 130a to 130g are exposed.

In some embodiments, the dummy gate structures 130f and 130g are replaced with dielectric gates 125a and 125b (see FIG. 10A). In some embodiments, an etching process may be performed to remove the dummy gate structures 130f and 130g and their underlying structures, to form recesses. Then, dielectric materials are formed in the recesses and serve as the dielectric gates 125a and 125b.

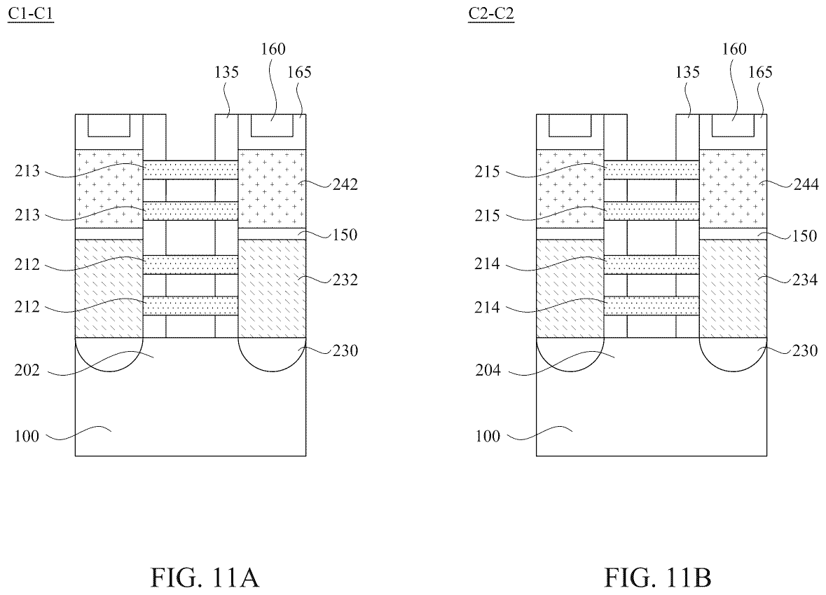

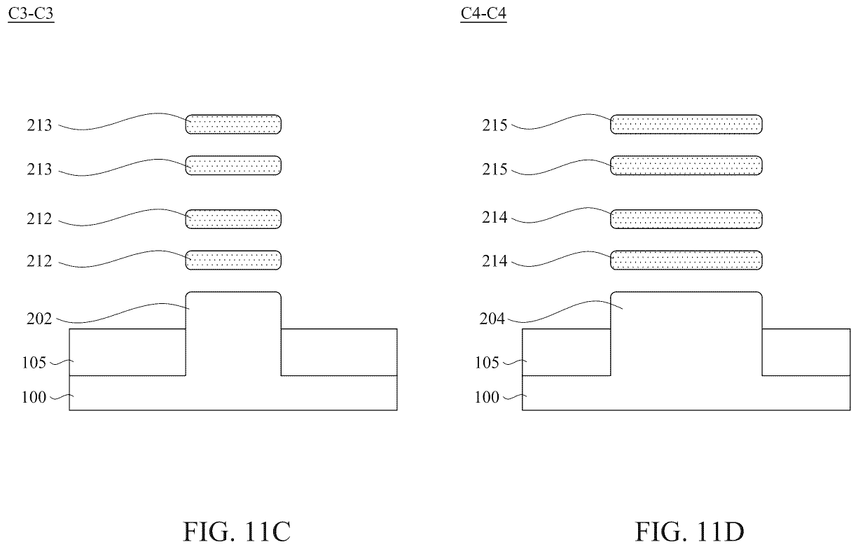

Reference is made to FIGS. 11A to 11D. The dummy gate structures 130a to 130e are removed to form gate trenches between the respective spacers 135. Then, the sacrificial layers 210 and 211 are removed using suitable etching process, such that the semiconductor sheets 212, 213, 214, and 215 are suspended over the substrate 100.

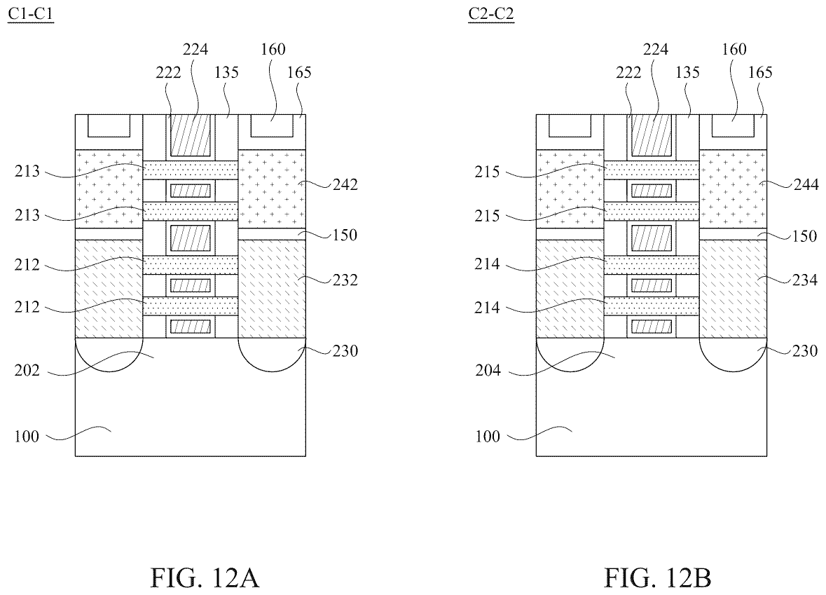

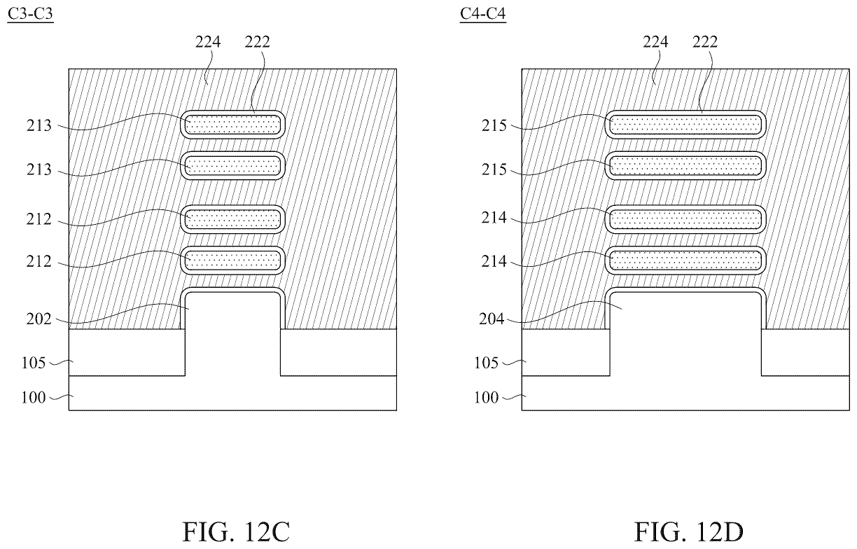

Reference is made to FIGS. 12A to 12D. Gate dielectrics 222 are formed ion the gate trenches and over the exposed surfaces of the semiconductor strips 202 and 204, and the semiconductor sheets 212, 213, 214, and 215. Afterwards, bottom electrodes 224 are formed in the gate trenches, such that the bottom electrode 224 may wrap around the semiconductor sheets 212, 213, 214, and 215. In some embodiments, the bottom electrodes 224 may be formed by, for example, depositing one or more conductive materials in the gate trenches, and then performing the planarization process (e.g., CMP) to remove excess conductive materials until the ILD layer 160 is exposed.

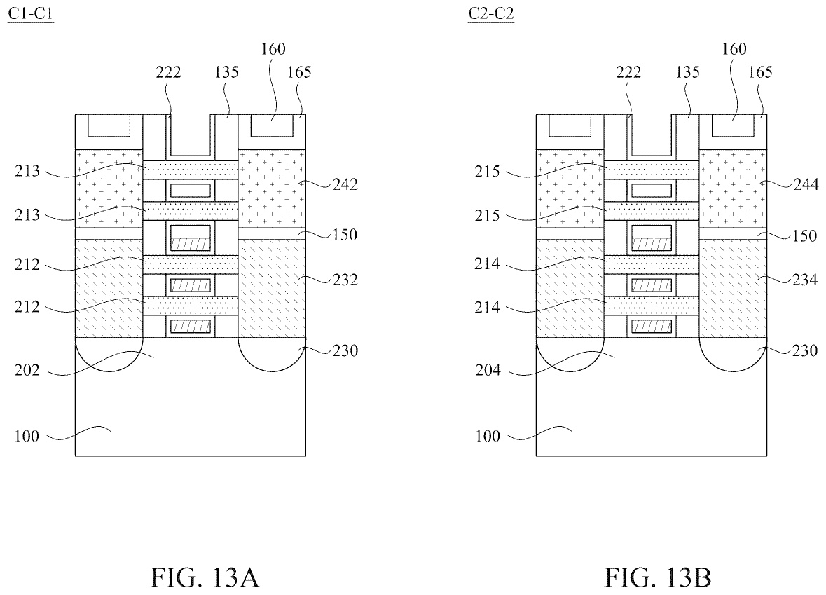

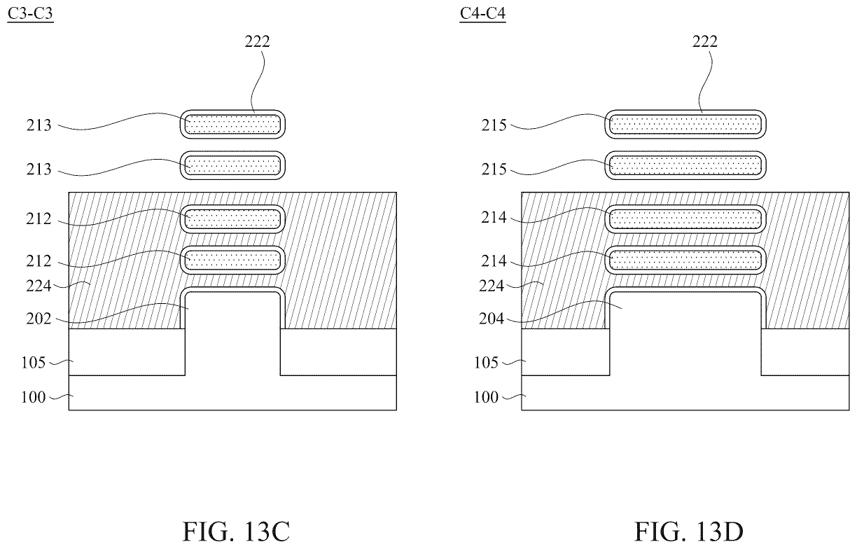

Reference is made to FIGS. 13A to 13D. An etching back process is performed to the bottom electrodes 224, so as to remove top portions of the bottom electrodes 224. That is, top surfaces of the bottom electrodes 224 are lowered as a result of the etching back process. In some embodiments, the top surfaces of the bottom electrodes 224 are lowered to a position between the topmost semiconductor sheet 212 and the bottommost semiconductor sheet 213 and between the topmost semiconductor sheet 214 and the bottommost semiconductor sheet 215.

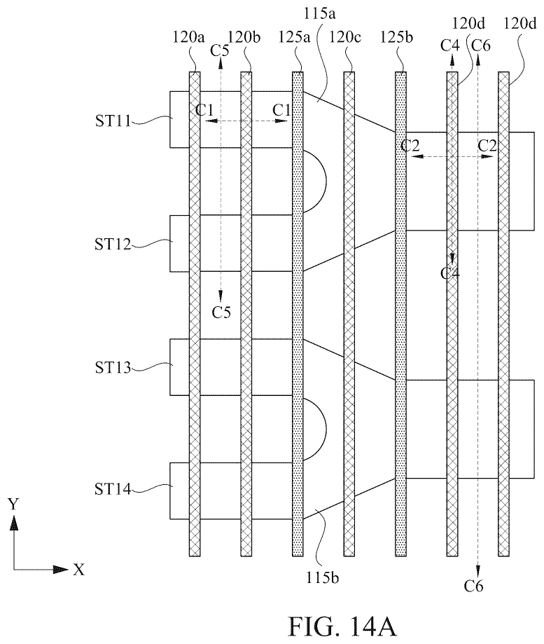

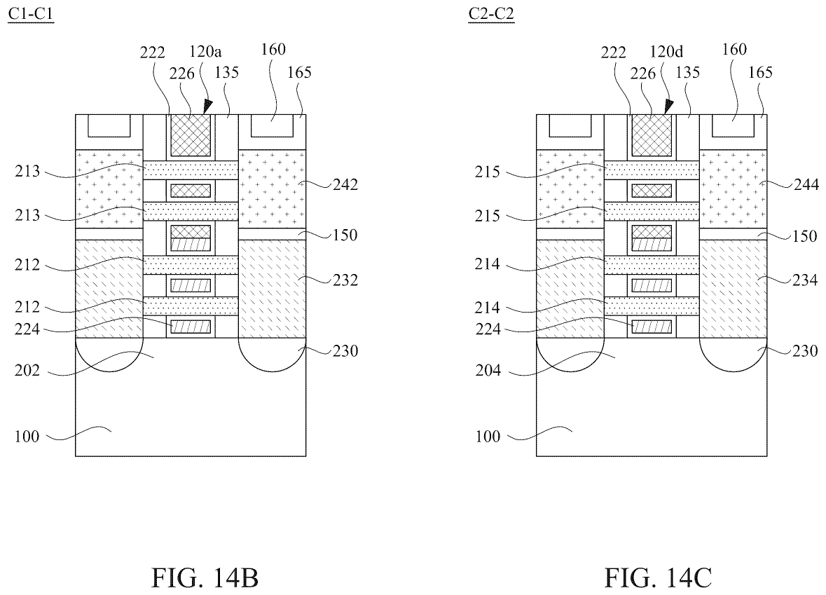

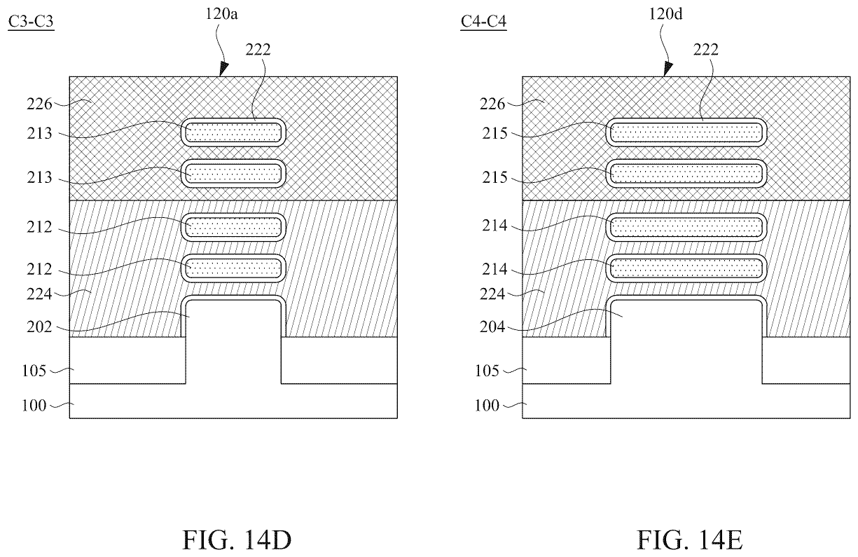

Reference is made to FIGS. 14A to 14E. Top electrodes 226 are formed in the gate trenches and over the bottom electrodes 224, such that the top electrodes 226 may wrap around the semiconductor sheets 213 and 215. As a result, gate structures 120a to 120e are formed. In some embodiments, the top electrodes 226 may be formed by, for example, depositing one or more conductive materials in the gate trenches, and then performing the planarization process (e.g., CMP) to remove excess conductive materials until the ILD layer 160 is exposed.

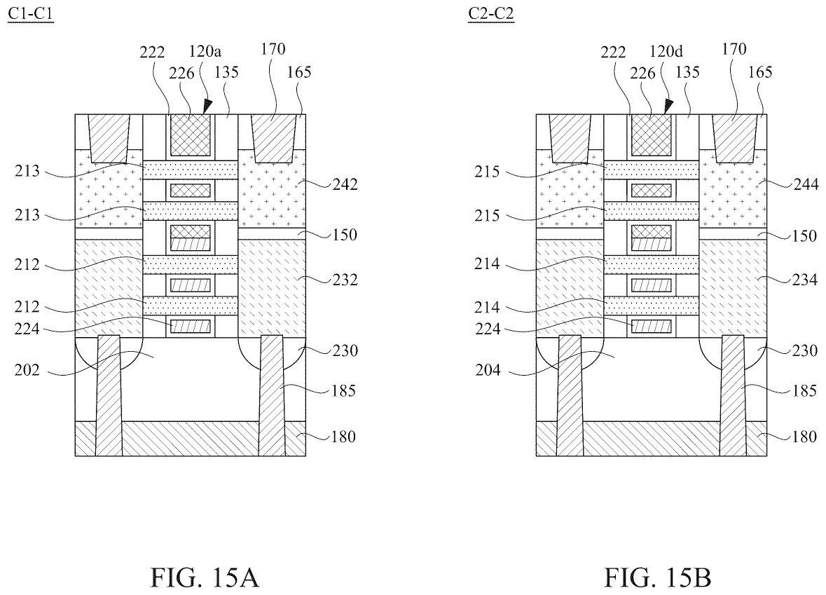

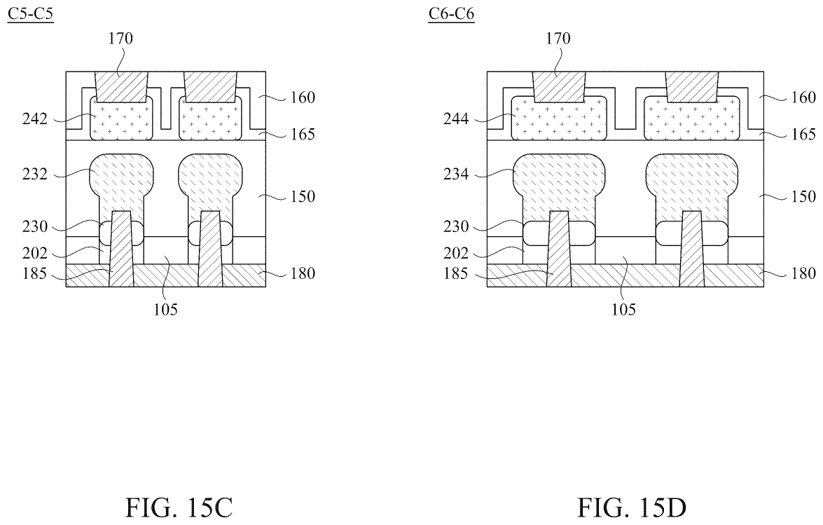

Reference is made to FIGS. 15A to 15D. After the gate structures 120a to 120e are formed, source/drain contacts 170 are formed extending through the ILD layer 160 and the CESL 165 and are electrically connected with the respective source/drain regions 242 and 244. In some embodiments, the source/drain contacts 170 can be formed by, for example, patterning the ILD layer 160 and the CESL 165 to form openings that expose the source/drain regions 242 and 244, depositing one or more conductive materials in the openings, and then performing the planarization process (e.g., CMP) to remove excess conductive materials until the ILD layer 160 is exposed. In some embodiments, an interconnect structure (not shown) may be formed over the ILD layer 160.

Then, the substrate 100 is removed, so as to expose the isolation structures 105. In some embodiments, the structure of FIGS. 14A to 14E may be flipped over by, for example, 180 degrees, and a grinding process may be performed on the backside of the substrate 100, so as to remove portions of the substrate 100 until the isolation structures 105, and the semiconductor strips 202 and 204 are exposed.

A dielectric layer 180 is then formed along surfaces of the semiconductor strips 202 and 204, and the isolation structures 105. In some embodiments, the dielectric layer 180 can be formed by suitable deposition process, such CVD, ALD, or the like.

Source/drain contacts 185 are than extending through the dielectric layer 180, the respective semiconductor strips 202 and 204, the respective isolation layers 230, and electrically connected with the respective source/drain regions 232 and 242. In some embodiments, the source/drain contacts 185 can be formed by, for example, patterning the dielectric layer 180, the semiconductor strips 202 and 204, and the isolation layers 230 to form openings that expose the source/drain regions 232 and 242, depositing one or more conductive materials in the openings, and then performing the planarization process (e.g., CMP) to remove excess conductive materials until the dielectric layer 180 is exposed.

FIG. 16 illustrates a top view of an integrated circuit in accordance with some embodiments of the present disclosure. It is noted that some elements of FIG. 16 have been described above, such elements may be labeled the same, and relevant details will not be repeated for brevity.

Shown there is integrated circuit 10b. The integrated circuit 10b may be similar to the integrated circuit 10a as discussed above, while the difference is that the width W2 of the semiconductor layers 114a and 114b may be substantially the same as the sum of two times the width W1 and the distance S1. That is, the relationship among the widths W1 and W2 and the distance S1 can be expressed as W2=2*W1+S1. In some embodiments where the integrated circuit 10b satisfy W2=2*W1+S1 and W2+S2=2*(W1+S1), the distances S1 and S2 may be substantially the same (e.g., S1=S2).

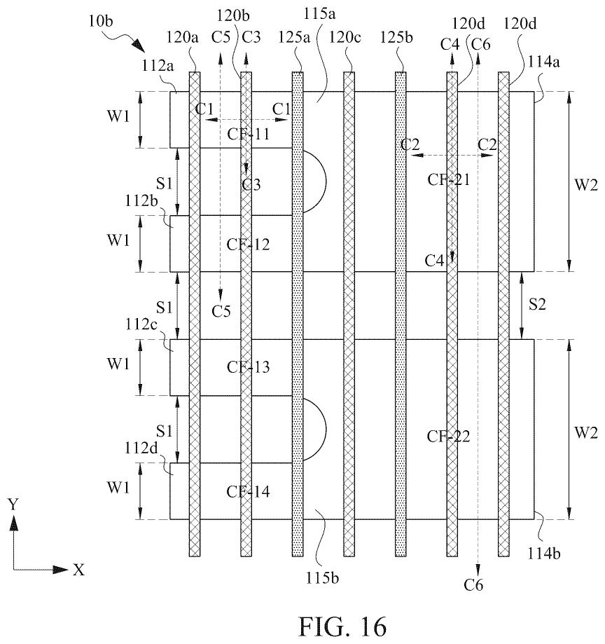

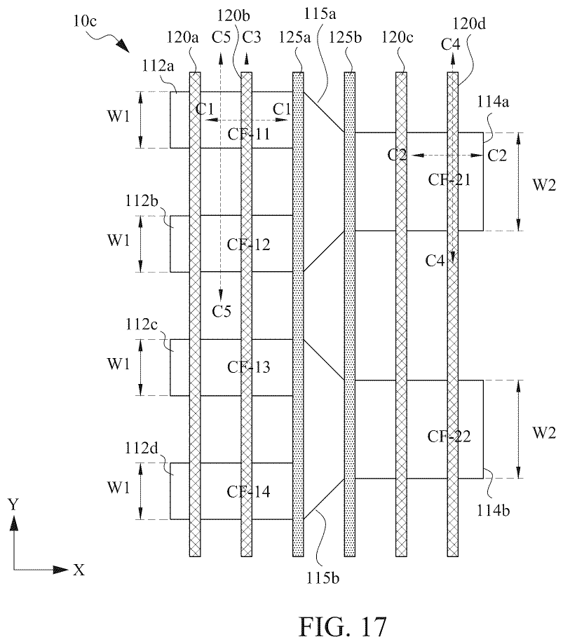

FIG. 17 illustrates a top view of an integrated circuit in accordance with some embodiments of the present disclosure. It is noted that some elements of FIG. 17 have been described above, such elements may be labeled the same, and relevant details will not be repeated for brevity.

Shown there is integrated circuit 10c. The integrated circuit 10c may be similar to the integrated circuit 10a as discussed above, while the difference is that the gate structure 120c of the integrated circuit 10a may be omitted in the integrated circuit 10c.

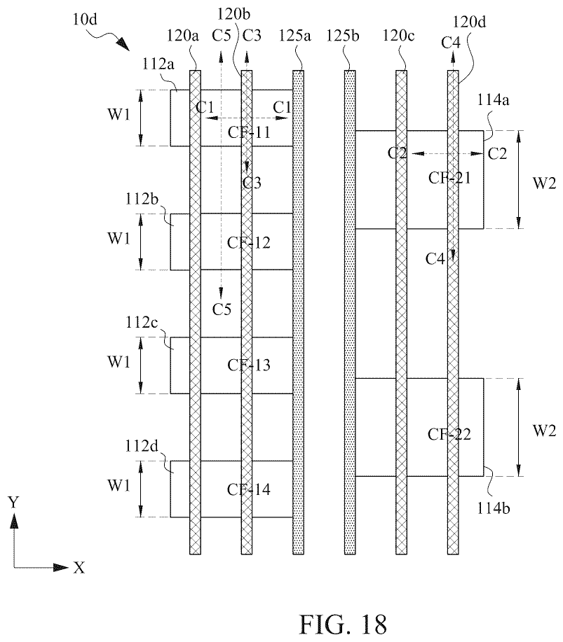

FIG. 18 illustrates a top view of an integrated circuit in accordance with some embodiments of the present disclosure. It is noted that some elements of FIG. 18 have been described above, such elements may be labeled the same, and relevant details will not be repeated for brevity.

Shown there is integrated circuit 10d. The integrated circuit 10d may be similar to the integrated circuit 10a as discussed above, while the difference is that the jog regions 115a and 115b of the integrated circuit 10a may be omitted in the integrated circuit 10d.

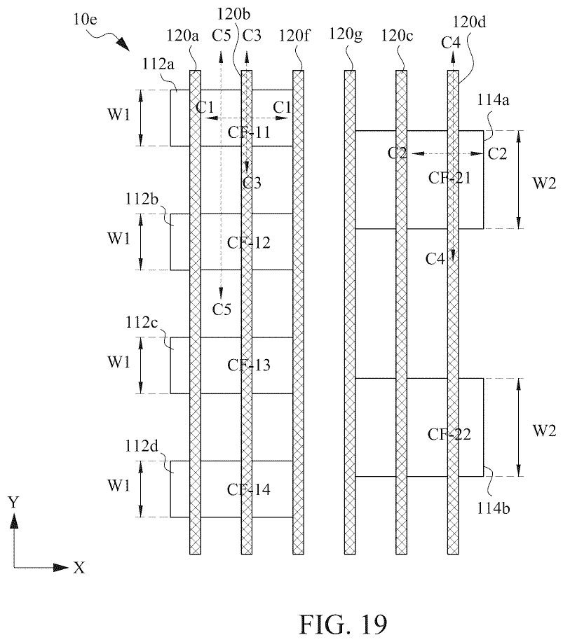

FIG. 19 illustrates a top view of an integrated circuit in accordance with some embodiments of the present disclosure. It is noted that some elements of FIG. 19 have been described above, such elements may be labeled the same, and relevant details will not be repeated for brevity.

Shown there is integrated circuit 10e. The integrated circuit 10e may be similar to the integrated circuit 10a as discussed above, while the difference is that the jog regions 115a and 115b of the integrated circuit 10a may be omitted in the integrated circuit 10e, and the dielectric gates 125a and 125b of the of the integrated circuit 10a may be replaced with gate structures 120f and 120g as shown in the integrated circuit 10e. In some embodiments, the gate structures 120f and 120g may include similar configuration as the gate structures 120a to 120e as discussed above.

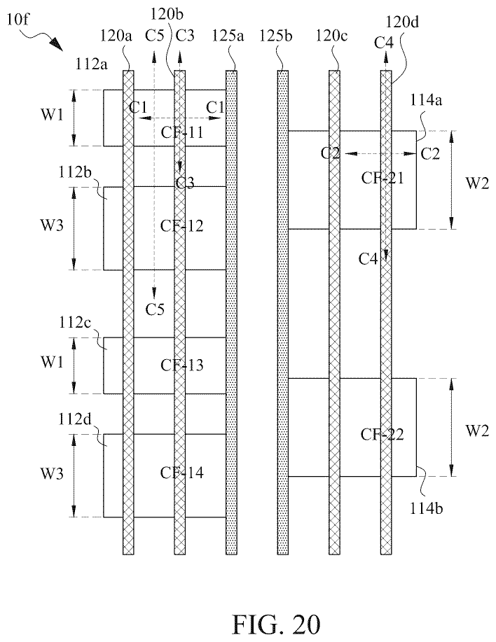

FIG. 20 illustrates a top view of an integrated circuit in accordance with some embodiments of the present disclosure. It is noted that some elements of FIG. 19 have been described above, such elements may be labeled the same, and relevant details will not be repeated for brevity.

Shown there is integrated circuit 10f. The integrated circuit 10e may be similar to the integrated circuit 10a as discussed above, while the difference is that the semiconductor layers 112b and 112d may include a width W3. The width W3 may be different from the width W1. For example, the width W3 may be greater than the width W1 and may be less than the width W2. In some embodiments, the width W2 may be substantially the same as the sum of the width W1 and the width W3. That is, the widths W1, W2, and W3 may satisfy W2=W1+W3.

According to the aforementioned embodiments, it can be seen that the present disclosure offers advantages in fabricating integrated circuits. It is understood, however, that other embodiments may offer additional advantages, and not all advantages are necessarily disclosed herein, and that no particular advantage is required for all embodiments. Embodiments of the present disclosure provide an integrated circuit having several groups of CFETs, in which the channel regions of a first group of CFETs may include a different width than the channel regions of a second group of CFETs, and the gate pitch of the second group of CFETs may be twice the gate pitch of the first group of CFETs. Such configuration may be beneficial for reducing cell height, and will further provide higher device density and moderate device spacing. Accordingly, with such configuration, the device performance can be improved.

In some embodiments of the present disclosure, a semiconductor structure includes a first group of a first transistor and a second transistor, the first and second transistors being arranged along a first direction, wherein the first and second transistors includes channel regions having a width W1 along the first direction, and the first and second transistors include a distance S1 therebetween. The semiconductor structure includes a second group of third transistor and a fourth transistor, the third and fourth transistors being arranged along the first direction, wherein the third and fourth transistors includes channel regions having a width W2 along the first direction, and the third and fourth transistors include a distance S2 therebetween, and wherein W2+S2 is greater than W1+S1.

In some embodiments, the width W2 is substantially the same as n times the width W1, and n is in a range from 2 to 6.

In some embodiments, n32 2, and the distance S2 is substantially the same as two times the distance S1.

In some embodiments, W2+S2 is substantially the same as two times (W1+S1).

In some embodiments, the width W2 is substantially the same as a sum of the distance S1 and two times the width W1.

In some embodiments, the distance S1 is substantially the same as the distance S2.

In some embodiments, the first, second, third, and fourth transistors each includes a bottom transistor and a top transistor vertically above the bottom transistor.

In some embodiments of the present disclosure, a semiconductor structure includes a substrate comprises a first semiconductor strip and a second semiconductor strip arranged along a first direction, a third semiconductor strip adjacent to the first and second semiconductor strips, and a transition region connecting the first, second, and third semiconductor strips, wherein the transition region has a varying width. A first transistor and a second transistor are over the first semiconductor strip and the second semiconductor strip, respectively. A third transistor is over the third semiconductor strip, wherein channel regions of third transistor are partially aligned with channel regions of the first transistor and channel regions of the second transistor along a second direction perpendicular to the first direction, and wherein along the first direction, a width W2 of the channel regions of the third transistor is greater than a width W1 of the channel regions of the first transistor, and wherein the width W2 is substantially the same as n times the width W1, where n is a positive integer.

In some embodiments, the channel regions of the second transistor have the width W1 along the first direction.

In some embodiments, the semiconductor structure further includes a fourth transistor, the fourth transistor and the third transistor being arranged along the first direction, the channel regions of the second transistor has the width W1 along the first direction, channel regions of the fourth transistor has the width W2 along the first direction, the channel regions the first and second transistors include a distance S1 therebetween, and the channel regions the third and fourth transistors include distance S2 therebetween, wherein W2+S2 is substantially the same as two times (W1+S1).

In some embodiments, n=2, and the distance S2 is substantially the same as two times the distance S1.

In some embodiments, the width W2 is substantially the same as a sum of the distance S1 and two times the width W1.

In some embodiments, the width W1 of the channel regions of the first transistor is different from a width W3 of the channel regions of the second transistor.

In some embodiments, the width W3 is greater than the width W1 and is less than the width W2.

In some embodiments, the first, second, and third transistors each includes a bottom transistor and a top transistor vertically above the bottom transistor.

In some embodiments of the present disclosure, a method includes forming first channel layers and second channel layers arranged along a first direction, and third channel layers and fourth channel layers arranged along the first direction, wherein the first and second channel layers includes a width W1 along the first direction, and the first and second channel layers include a distance S1 therebetween, the third and fourth channel layers includes a width W2 along the first direction, and the third and fourth channel layers include a distance S2 therebetween, wherein W2+S2 is greater than W1+S1; forming source/drain regions on opposite ends of the first, second, third, and fourth channel layers; and forming a first gate structure wrapping around the first and second channel layers and a second gate structure wrapping around the third and fourth channel layers.

In some embodiments, the width W2 is substantially the same with two times the width W1, and the distance S2 is substantially the same as two times the distance S1.

In some embodiments, W2+S2 is substantially the same as two times (W1+S1).

In some embodiments, the width W2 is substantially the same as a sum of the distance S1 and two times the width W1.

In some embodiments, the distance S1 is substantially the same as the distance S2.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor structure, comprising:
a first group of a first transistor and a second transistor, the first and second transistors being arranged along a first direction, wherein the first and second transistors includes channel regions having a width W1 along the first direction, and the first and second transistors include a distance S1 therebetween; and
a second group of third transistor and a fourth transistor, the third and fourth transistors being arranged along the first direction, wherein the third and fourth transistors includes channel regions having a width W2 along the first direction, and the third and fourth transistors include a distance S2 therebetween, and wherein W2+S2 is greater than W1+S1.

2. The semiconductor structure of claim 1, wherein the width W2 is substantially the same as n times the width W1, and n is in a range from 2 to 6.

3. The semiconductor structure of claim 2, wherein n=2, and the distance S2 is substantially the same as two times the distance S1.

4. The semiconductor structure of claim 1, wherein W2+S2 is substantially the same as two times (W1+S1).

5. The semiconductor structure of claim 1, wherein the width W2 is substantially the same as a sum of the distance S1 and two times the width W1.

6. The semiconductor structure of claim 5, wherein the distance S1 is substantially the same as the distance S2.

7. The semiconductor structure of claim 1, wherein the first, second, third, and fourth transistors each includes a bottom transistor and a top transistor vertically above the bottom transistor.

8. A semiconductor structure, comprising:
a substrate comprises a first semiconductor strip and a second semiconductor strip arranged along a first direction, a third semiconductor strip adjacent to the first and second semiconductor strips, and a transition region connecting the first, second, and third semiconductor strips, wherein the transition region has a varying width;
a first transistor and a second transistor over the first semiconductor strip and the second semiconductor strip, respectively; and
a third transistor over the third semiconductor strip, wherein channel regions of third transistor are partially aligned with channel regions of the first transistor and channel regions of the second transistor along a second direction perpendicular to the first direction, and wherein along the first direction, a width W2 of the channel regions of the third transistor is greater than a width W1 of the channel regions of the first transistor, and wherein the width W2 is substantially the same as n times the width W1, where n is a positive integer.

9. The semiconductor structure of claim 8, wherein the channel regions of the second transistor have the width W1 along the first direction.

10. The semiconductor structure of claim 8, further comprising a fourth transistor, the fourth transistor and the third transistor being arranged along the first direction, the channel regions of the second transistor has the width W1 along the first direction, channel regions of the fourth transistor has the width W2 along the first direction, the channel regions the first and second transistors include a distance S1 therebetween, and the channel regions the third and fourth transistors include distance S2 therebetween, wherein W2+S2 is substantially the same as two times (W1+S1).

11. The semiconductor structure of claim 10, wherein n=2, and the distance S2 is substantially the same as two times the distance S1.

12. The semiconductor structure of claim 10, wherein the width W2 is substantially the same as a sum of the distance S1 and two times the width W1.

13. The semiconductor structure of claim 8, wherein the width W1 of the channel regions of the first transistor is different from a width W3 of the channel regions of the second transistor.

14. The semiconductor structure of claim 13, wherein the width W3 is greater than the width W1 and is less than the width W2.

15. The semiconductor structure of claim 8, wherein the first, second, and third transistors each includes a bottom transistor and a top transistor vertically above the bottom transistor.

16. A method, comprising:
forming first channel layers and second channel layers arranged along a first direction, and third channel layers and fourth channel layers arranged along the first direction, wherein the first and second channel layers includes a width W1 along the first direction, and the first and second channel layers include a distance S1 therebetween, the third and fourth channel layers includes a width W2 along the first direction, and the third and fourth channel layers include a distance S2 therebetween, wherein W2+S2 is greater than W1+S1;
forming source/drain regions on opposite ends of the first, second, third, and fourth channel layers; and
forming a first gate structure wrapping around the first and second channel layers and a second gate structure wrapping around the third and fourth channel layers.

17. The method of claim 16, wherein the width W2 is substantially the same with two times the width W1, and the distance S2 is substantially the same as two times the distance S1.

18. The method of claim 17, wherein W2+S2 is substantially the same as two times (W1+S1).

19. The method of claim 16, wherein the width W2 is substantially the same as a sum of the distance S1 and two times the width W1.

20. The method of claim 19, wherein the distance S1 is substantially the same as the distance S2.
